(19) United States
(12) Patent Application Publication
(10) Pub. No.: US 2007/0187675 A1
(43) Pub. Date: Aug. 16, 2007

(54) Organic light emitting device

(76) Inventors: Tae-Woo Lee, Seoul (KR); Shinichiro Tamura, Seongnam-si (KR); Jong-Jin Park, Yongin-si (KR); O-Hyun Kwon, Seoul (KR); Joon-Yong Park, Yongin-si (KR); Mu-Gyeom Kim, Hwaseong-si (KR)

Correspondence Address: Robert E. Bushnell, Suite 300, 1522 K Street, N.W., Washington, DC, 20005, US

(21) Appl. No.: 11/650,429

(22) Filed: Jan. 8, 2007

(30) Foreign Application Priority Data
Feb. 13, 2006 (KR) 10-2006-0013699

(51) Int. Cl. H01L 51/54; H01L 51/52

(52) U.S. Cl. 257/40; 428/690; 428/917; 313/504; 313/506; 257/101; 257/E51.027

(57) ABSTRACT

Provided is an organic light emitting device that includes at least one organic layer between a first electrode and an emissive layer wherein the organic layer includes at least two organic materials and at least one of the organic materials consequently has a concentration gradient in the direction from the first electrode to a second electrode through a single solution process by self organization. Since the organic layer has a work function having a gradient in the direction from the first electrode to the second electrode, holes can be injected from the first electrode to the emissive layer, and thereby an organic light emitting device having high efficiency and a long lifetime can be obtained.

### CROSS-REFERENCE TO RELATED PATENT APPLICATION AND CLAIM OF PRIORITY

This application claims the benefit of Korean Patent Application No. 10-2006-0013699, filed on Feb. 13, 2006 in the Korean Intellectual Property Office, the disclosure of which is incorporated herein in its entirety by reference.

### BACKGROUND OF THE INVENTION

1. Field of the Invention

The present invention relates to an organic light emitting device, and more particularly, to an organic light emitting device that includes at least one organic layer, including at least two organic materials, between a first electrode and an emissive layer, wherein the organic layer is formed through a single solution process by self organization and at least one of the organic materials consequently has a concentration gradient by self organization in the direction from the first electrode toward a second electrode.

2. Description of the Related Art

An organic light emitting device is a self-emissive display device using the principle that when current is applied to a fluorescent or phosphorescent organic compound thin layer (hereinafter referred to as ‘organic layer’), electrons and holes combine in the organic layer and thus light is generated. An organic light emitting device can be made light, is easy to manufacture because of simple elements thereof, and can provide a wide viewing angle and a high quality image. Also, a light emitting device can realize perfect moving images and high color purity and can be operated at low power and low voltage, and thus is appropriate for mobile electronic devices.

Organic light emitting devices can be classified into small molecule organic light emitting devices and polymer light emitting devices, depending on the material and the process forming the organic layer.

Small molecule organic light emitting devices can be manufactured using a vacuum deposition method. In small molecule organic light emitting devices, the light emitting material can be easily purified, high purity can be easily obtained, and color pixels can be easily realized. Despite the advantages of small molecule organic light emitting devices, improvements are still required for practical application, for example, improvement of quantum efficiency and color purity and preventing the thin layers from being crystallized.

Since the Cambridge group reported in 1990 that light is emitted when power is applied to a poly(1,4-phenylenvinylene)(PPV), which is a π-conjugated polymer, research into a light emitting device using a polymer has been vigorously conducted. A π-conjugated polymer has a chemical structure in which a single bond (or σ-bond) and a double bond (or π-bond) are alternated, and thus has a π-electron that can move relatively freely according to the bonding chain without being localized. Due to the semiconductor property of the π-conjugated polymer, when the π-conjugated polymer is applied to an emissive layer of an electroluminescent device, light of the entire region corresponding to a HOMO-LUMO band-gap can be easily obtained using a molecular design. Also, when the π-conjugated polymer is used, thin films can be formed in a simple way using a spin-coating or printing method, which simplifies the manufacturing process of the device and reduces costs, and since the π-conjugated polymer has a high glass transition temperature, a thin film having excellent mechanical properties can be provided. Accordingly, an EL device using a polymer is expected to have greater commercial competency than a small molecule light emitting device in the long run.

Such a polymer light emitting device includes not only a single emissive layer as an organic layer for improving efficiency and reducing driving voltage, but has a multi-layer structure including a hole injection layer, an emissive layer, an electron injection layer, etc. using conducting polymers.

In particular, a poly(3,4-ethylenedioxythiophene)-PSS(poly(4-styrene-sulfonate) (PEDOT) solution which is manufactured by Bayer AG and sold under the name Baytron-P is widely used to be spin-coated on an indium tin oxide (ITO) electrode for forming a hole injection layer when an light emitting device is manufactured. The hole injection material PEDOT-PSS has a structure as represented below.

However, the PEDOT/PSS composition has a work function of 5.0 through 5.2, and thus is not advantageous for hole injection because the energy barrier between a polyfluorene derivative having a highest occupied molecular orbit (HOMO) value (mostly greater than 5.5 eV) and the PEDOT/PSS composition is greater than 0.3 eV which makes hole injection difficult. Also, even though a material having a hole injection layer work function of 5.5 eV or greater is synthesized (a material having a hole injection layer work function of 5.5 eV or greater has not been reported yet), a work function of ITO that is used as an anode mainly in OLEDs is 4.7 through 4.9 eV. Thus an energy barrier is present between ITO and PEDOT/PSS, and hole injection is difficult.

Accordingly, in order to overcome the energy barrier between the ITO electrode and the HOMO of the emissive layer, a new organic light emitting device needs to be developed.

### SUMMARY OF THE INVENTION

The present invention provides an improved organic light emitting device.

The present invention also provides a compound which may be used as a hole injection material or a hole transport material with a conjugated compound.

The compound may be represented by Formula 1:

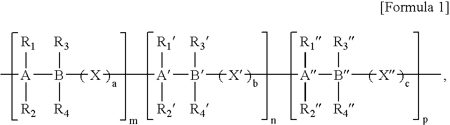

where 0<m<10,000,000, 0≦n<10,000,000, 0≦p<10,000,000, 0≦a≦20,0≦b≦20,0≦c≦20;

A, B, A′, B′, A″, and B″ are each independently selected from C, Si, Ge, Sn, and Pb;

R₁, R₂, R₃, R₄, R₁′, R₂′, R₃′, R₄′, R₁″, R₂″, R₃″, and R₄″ are each independently selected from the group consisting of hydrogen, halogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted. C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group, and a substituted or unsubstituted C6-C30 heteroarylester group;

when 0<n<10,000,000, at least one of R₁, R₂, R₃, R₄, R₁′, R₂′, R₃′, and R₄′ is fluorine or a group substituted with fluorine, and at least one of R₁, R₂, R₃, and R₄ is an ionic group or comprises an ionic group;

when n=0, at least one of R₁, R₂, R₃, and R₄ is fluorine or a group substituted with fluorine, and at least one of R₁, R₂, R₃, and R₄ is an ionic group or comprises an ionic group; and

X, X′, and X″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, where X, X′, and X″ may be selectively substituted or unsubstituted with fluorine.

According to an aspect of the present invention, there is provided an organic light emitting device comprising: a first electrode; an emissive layer formed on the first electrode; a second electrode formed on the emissive layer; and an organic layer between the first electrode and the emissive layer, the organic layer comprising at least two organic materials, at least one of said at least two organic materials having a concentration gradient in the direction from the first electrode to the second electrode.

The organic layer may be formed by self-organization through a single solution process.

The organic light emitting device may further comprise at least one another organic layer comprising at least one organic material between the first electrode and the emissive layer, and at least one organic material of the another organic material has no concentration gradient in the direction from the first electrode to the second electrode.

The organic layer may be a hole injection layer or a hole transporting layer.

At least one of the organic materials may have a concentration decreasing in the direction from the first electrode to the second electrode.

The absolute values of the ionization energy, the work function, and highest occupied molecular orbital (HOMO) in the organic layer may increase in the direction from the first electrode to the second electrode.

The organic layer may comprise a conjugated compound and a compound represented by Formula 1:

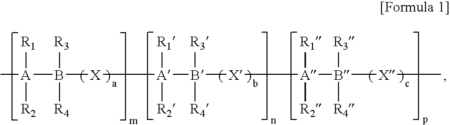

where 0<m<10,000,000, 0≦n<10,000,000, 0≦p<10,000,000, 0≦a≦20, 0≦b≦20, 0≦c≦20;

A, B, A′, B′, A″, and B″ are each independently selected from C, Si, Ge, Sn, and Pb;

R₁, R₂, R₃, R₄, R₁′, R₂′, R₃′, R₄′, R₁″, R₂″, R₃″, and R₄″ are each independently selected from the group consisting of hydrogen, halogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group, and a substituted or unsubstituted C6-C30 heteroarylester group;

when 0<n<10,000,000, at least one of R₁, R₂, R₃, R₄, R₁′, R₂′, R₃′, and R₄′ is fluorine or a group substituted with fluorine, and at least one of R₁, R₂, R₃, and R₄ is an ionic group or comprises an ionic group;

when n=0, at least one of R₁, R₂, R₃, and R₄ is fluorine or a group substituted with fluorine, and at least one of R₁, R₂, R₃, and R₄ is an ionic group or comprises an ionic group; and

X, X′, and X″ are each independently selected from the group consisting of a bond, O, S, a substituted or unsubstituted C1-C30 alkylene group, a substituted or unsubstituted C₁-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, where X, X′, and X″ may be selectively substituted or unsubstituted with fluorine.

The conjugated compound may be a conductive compound substituted or unsubstituted with an ionic group or a semi-conductive compound that is substituted or unsubstituted with an ionic group.

At least one of the conjugated compound and the compound represented by Formula 1 may have a concentration gradient in the direction from the first electrode to the second electrode.

Preferably, the compound represented by Formula 1 may be 10 to 5,000 parts by weight based on 100 parts by weight of the conjugated compound.

The organic layer may further comprise a compound represented by Formula 13:

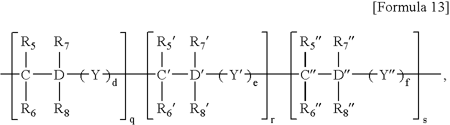

where 0<q<10,000,000, 0≦r<10,000,000, 0≦s<10,000,000, 0≦d<20, 0≦e≦20, and 0≦f≦20;

C, D, C′, D′, C″, and D″ are each independently selected from the group consisting of C, Si, Ge, Sn, and Pb;

R₅, R₆, R₇, R₈, R₅′, R₆′, R₇′, R₈′, R₅″, R₆″, R₇″, and R₈″ are each independently selected from the group consisting of hydrogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group and a substituted or unsubstituted C6-C30 heteroarylester group, and the substituent of the substituted group is not fluorine;

at least one of R₆, R₇, R₈, R₉, R₆′, R₇′, R₈′, and R₉′ is an ionic group or comprises an ionic group; and

Y, Y′, and Y″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, and the substituent of the substituted group is not fluorine.

According to an aspect of the present invention, there is provided an organic light emitting device comprising: a substrate; a first electrode on the substrate; an emissive layer formed on the first electrode; a second electrode formed on the emitting layer; and an organic layer interposed between the first electrode and the emissive layer, the organic layer comprising a conjugated compound and the compound represented by Formula 1, at least one of the conjugated compound and the compound represented by Formula 1 having a concentration gradient in the direction from the first electrode to the second electrode.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A through 1D are cross-sectional views of an organic light emitting device according to an embodiment of the present invention;

FIGS. 2A and 2B are graphs illustrating results of analysis of a thin film of an organic light emitting device by X-ray photoelectron spectroscopy of Comparative Sample A and Sample 3 according to an embodiment of the present invention;

FIG. 3 illustrates energy diagrams of a conventional organic light emitting device and an organic light emitting device according to an embodiment of the present invention, respectively;

FIG. 4 is a graph illustrating efficiency characteristics of organic light emitting devices according to embodiments of the present invention;

FIG. 5 is a graph illustrating efficiency characteristics of organic light emitting devices according to other embodiments of the present invention; and

FIG. 6 is a graph illustrating the lifetimes of organic light emitting devices according to embodiments of the present invention.

### DETAILED DESCRIPTION OF THE INVENTION

The present invention will now be described in more detail.

An organic light emitting device according to an embodiment of the present invention includes at least one organic layer that includes at least two organic materials between a first electrode and an emissive layer and is formed through a single solution process by self organization, wherein at least one of the organic materials consequently has a concentration having an increasing gradient in the direction from the first electrode to a second electrode, and thus holes can be injected from the first electrode to the emissive layer. Thus, an organic light emitting device having high efficiency and a long lifetime can be obtained.

An organic light emitting device according to an embodiment of the present invention comprises: a first electrode formed on a substrate; an emissive layer formed on the first electrode; and a second electrode formed on the emissive layer, wherein at least one organic layer which includes at least two organic materials is formed between the first electrode and the emissive layer, and is formed by a self organization through a single solution process, wherein at least one of the organic materials has a concentration gradient in the direction from the first electrode to the second electrode.

Also, the organic light emitting device according to the current embodiment of the present invention may further include at least one another organic layer that includes at least one organic material and is formed between the first electrode and the emissive layer, wherein the organic material does not have a concentration gradient in the direction from the first electrode to the second electrode. That is, at least one organic layer having a concentration gradient as described above is formed on the first electrode, and at least one another organic layer which is formed of the conventional organic material having no concentration gradient can be formed on the first electrode.

The organic layer is at least one selected from a hole injection layer and a hole transporting layer in the organic light emitting device, and efficiently injects holes using an emissive polymer in a balanced way to improve light emitting intensity and efficiency of the organic EL device.

The organic layer includes at least two organic materials, one of which has a concentration that increases or decreases in the direction from the first electrode and the second electrode.

As a result, when the organic material, the concentration of which increases in the direction from the first electrode to the second electrode, has higher absolute values of ionization energy, work function, and HOMO compared to the other organic material(s), the ionization energy, work function, and HOMO of the organic layer itself increases in the direction from the first electrode to the second electrode.

The organic layer is formed through a single solution process by self organization, and thus at least one organic material included in the organic layer has a concentration gradient in the direction from the first electrode to the second electrode.

The single solution process used to form the organic layer refers to a process, for example, in which at least one organic material is dissolved or dispersed in a predetermined solvent, and coated on a predetermined substrate, and then dried and/or treated with heat.

The solvent provides predetermined viscosity to the organic materials as described before. The solvent is not limited as long as the solvent can dissolve or disperse the organic material. Examples of the solvent include water, alcohol, toluene, xylene, chlorobenzene, chloroform, di-chloroethane, dimethylformamide, dimethylsulfoxide, etc., but are not limited thereto.

Then a solution including an organic material is coated on a predetermined substrate using a conventional coating method such as spin-coating, dip coating, spray printing, ink-jet printing, nozzle printing, etc., but is not limited thereto. Next, the coated layer is dried and/or treated with heat to complete the formation of an organic layer.

The method used to form one of the organic materials in the organic layer to have a concentration gradient is not limited. An exemplary method uses the difference between the solubilities of the organic material to the solvents.

That is, when a solution is manufactured using a single solvent in which at least two organic materials have different solubilities, and then the solution is coated and then the solvent thereof is removed to form an organic layer, an organic material having lower solubility cannot be uniformly distributed in the organic layer and thus the concentration of the organic material increases either in the direction to the lower portion or in the direction to the upper portion of the organic layer. However, an organic material having a higher solubility can be uniformly distributed in general.

Also, when at least two solvents in which at least two organic materials have different solubilities are mixed to be used, the miscibility of the solvents decreases so that the solvents are phase-separated. Thus each organic material mainly dissolved in each solvent is differently distributed, and thus has a concentration gradient in the direction of the height of the organic layer which is formed by removing the solvents.

For example, when a hydrophilic organic material and a hydrophobic organic material are dissolved in a mixed solvent of a hydrophilic solvent and a hydrophobic solvent, the hydrophilic solvent dissolves the hydrophilic organic material, and the hydrophobic solvent dissolves the hydrophobic organic material so that the solvents will also be phase-separated. As a result, the organic layer formed by removing the mixed solvent has a concentration distribution. That is, from the lower portion to the upper portion of the organic layer, the hydrophilic organic material and the hydrophobic organic material have different concentration distributions through the organic layer.

As another example, a material formed of fluorocarbon and a material formed of hydrocarbon have low affinity to each other. However, a material of fluorocarbon with hydrophilicity (e.g., polystyrene sulfonate ionomer) and a material of hydrocarbon with hydrophilicity (e.g., polystyrene sulfonate ionomer) are dissolved in a hydrophilic solvent (water, alcohol, dimethylformamide, etc.) However, when the solution is removed through the solution process, the material containing fluorocarbon with hydrophilicity is likely to be mainly concentrated at the surface by self organization compared to a material containing hydrocarbon with hydrophilicity, thus obtaining a concentration gradient.

Besides, when at least two organic materials having different surface energies are used, the material having a lower surface energy tends to go to the surface during the solution process, at least one of the organic materials may have a concentration gradient in the organic layer.

Also, when at least two organic materials having different molecular weights are used, since a material having a lower molecular weight has a greater solubility and a faster mobility of segmental motion than a material having a greater molecular weight, and thus has a property to rise up to the surface when a thin film is formed through a solution process and heat treatment, at least one of the organic materials can have a concentration gradient in the organic layer.

However, the method of forming a gradient of a concentration of the organic material is not limited thereto.

Due to the formation of the gradient of the concentration of the organic material, the concentration of the organic material having high absolute values of work function, ionization energy, and HOMO increases in the direction from the first electrode to the second electrode, that is, toward the emissive layer. As a result, holes can be carried without generating any great energy barrier between the first electrode and the emissive layer, and thus the driving voltage is reduced and the service lifetime of the organic light emitting device is increased.

The organic layer contains a conjugated compound and a compound represented by Formula 1: 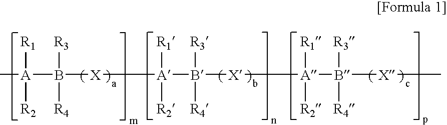
where 0<m<10,000,000, 0≦n<10,000,000, 0≦p<10,000,000, 0≦a≦20, 0≦b≦20, 0≦c≦20;

A, B, A′, B′, A″, and B″ are each independently selected from C, Si, Ge, Sn, and Pb;

R₁, R₂, R₃, R₄, R₁′, R₂′, R₃′, R₄′, R₁″, R₂″, R₃″, and R₄″ are each independently selected from the group consisting of hydrogen, halogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group, and a substituted or unsubstituted C6-C30 heteroarylester group; when n>0, at least one of R₁, R₂, R₃, R₄, R₁′, R₂′, R₃′, and R₄′ is fluorine or a group substituted with fluorine, and at least one of R₁, R₂, R₃, and R₄ is an ionic group or includes an ionic group;

when n=0, at least one of R₁, R₂, R₃, and R₄ is fluorine or a group substituted with fluorine, and at least one of R₁, R₂, R₃, and R₄ is an ionic group or includes an ionic group; and

X, X′, and X″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, where X, X′, and X″ may be selectively substituted or unsubstituted with fluorine.

The compounds represented by Formula 1 include at least one ionic group, and the ionic groups may be identical or different.

When 0<p<10,000,000, a first dopant of the present invention has a copolymerized structure with a nonionic monomer not having an ionic group, and thus the content of the ionic group in the conducting polymer decreases within an appropriate range, and as a result, the amount of the residue group decomposed by the reaction with electrons can be reduced. Here, the content of the nonionic comonomer is preferably 0.1 to 99 mol % (that is, 0.001<p/(m+n+p) <0.99), more preferably 1 to 50 mol % (that is, 0.01<p/(m+n+p) <0.5). When the content of the comonomer is less than 0.1 mol %, the comonomer cannot function as a nonionic group, and when the content of the comonomer is greater than 99 mol %, the ionic group is small and thus cannot function as a dopant.

When m>0, n=0, p=0, Formula 1 of the present invention neither includes a nonionic monomer nor is in copolymerization.

When m>0, n>0, p=0, Formula 1 of the present invention has a copolymerized structure that does not include a nonionic monomer.

As described above, at least one hydrogen of R₁, R₂, R₃, R₄, R₁′, R₂′, R₃′, and R₄′ in Formula 1 can be substituted with an ionic group or the ionic group itself can be directly substituted with B or B′. The ionic group is composed of an anionic group and a cationic group. The examples of the anionic group may be PO₃²⁻, SO₃⁻, COO⁻, I⁻, CH₃COO⁻, etc., and the examples of the cationic group paired with the anionic group may be a metal ion such as Na⁺, K⁺, Li⁺, Mg⁺², Zn⁺², and Al⁺³ or an organic ion such as H⁺, NH₄⁺, and CH₃(—CH₂—)ₙO⁺ (n is an integer from 0 through 50).

Also, when there are at least two cationic groups, Formula 1 preferably has an ionic group having different acidity in each monomer. For example, when one of R₁, R₂, R₃, is PO₃²⁻, one of R₁′, R₂′, R₃′, and R₄′ can be substituted with an ionic group selected from SO₃⁻, COO⁻, I⁻, CH₃COO⁻. When R₁, R₂, R₃, is SO₃⁻, one of R₁′, R₂′, R₃′, and R₄′ can be substituted with an ionic group selected from COO⁻, I⁻, and CH₃COO⁻.

A conjugated compound refers to a conductive compound substituted or unsubstituted with an ionic group or a semi-conductive compound substituted or unsubstituted with an ionic group.

The conductive compound may be selected from the group of polymers consisting of ethylenedioxythiophene (EDOT), aniline, pyrrole, acetylene, phenylene, phenylenevinylene, thiophene, and oligomer and polymer derivatives thereof.

Also, the semi-conductive compound has preferably at least one of the recurring units represented by Formulas 1A through 1AA, and a polymerization of 1 through 10,000,000.

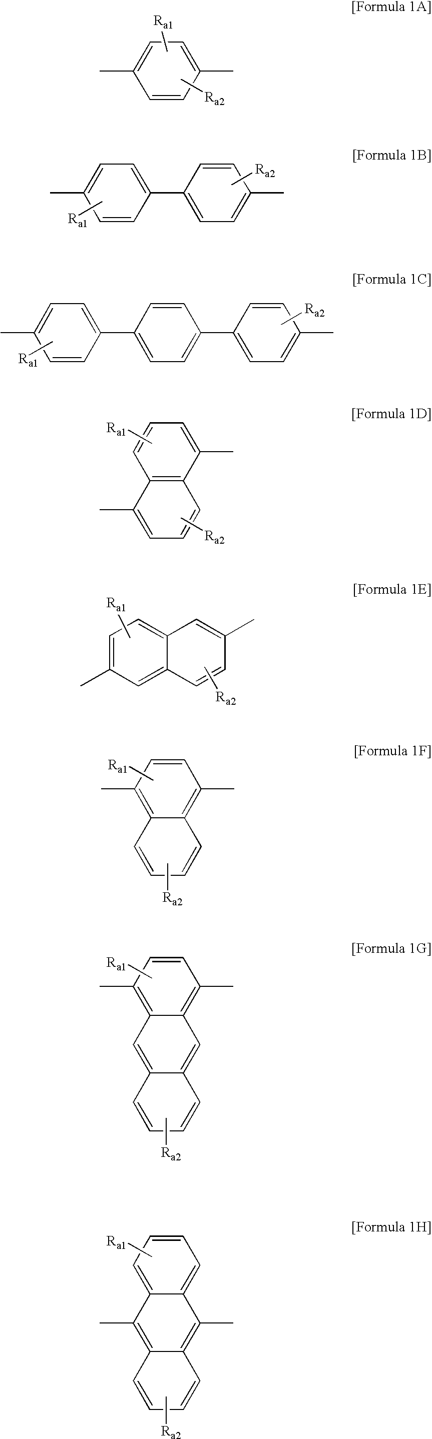

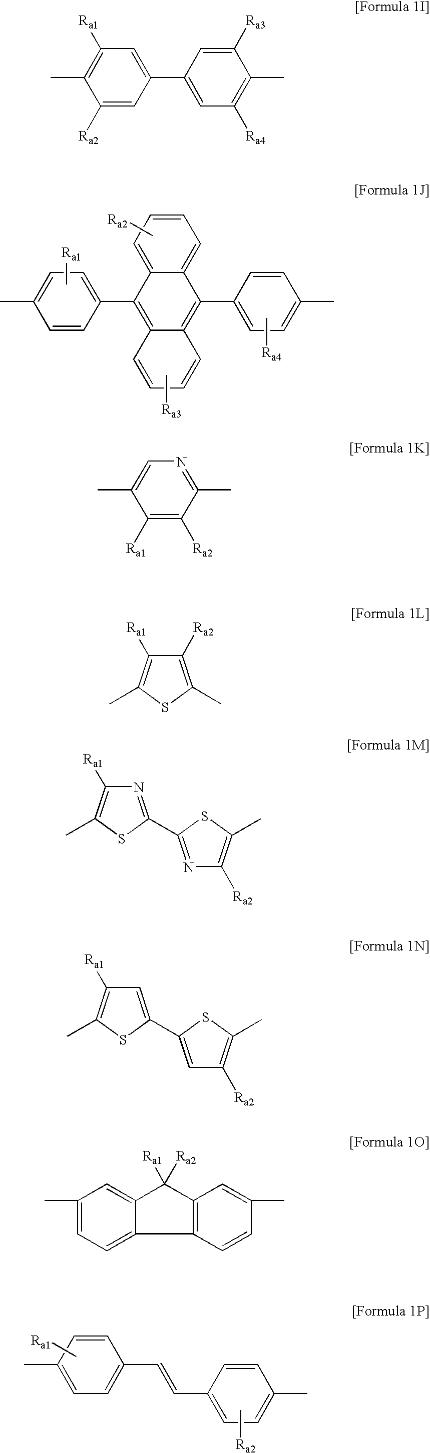

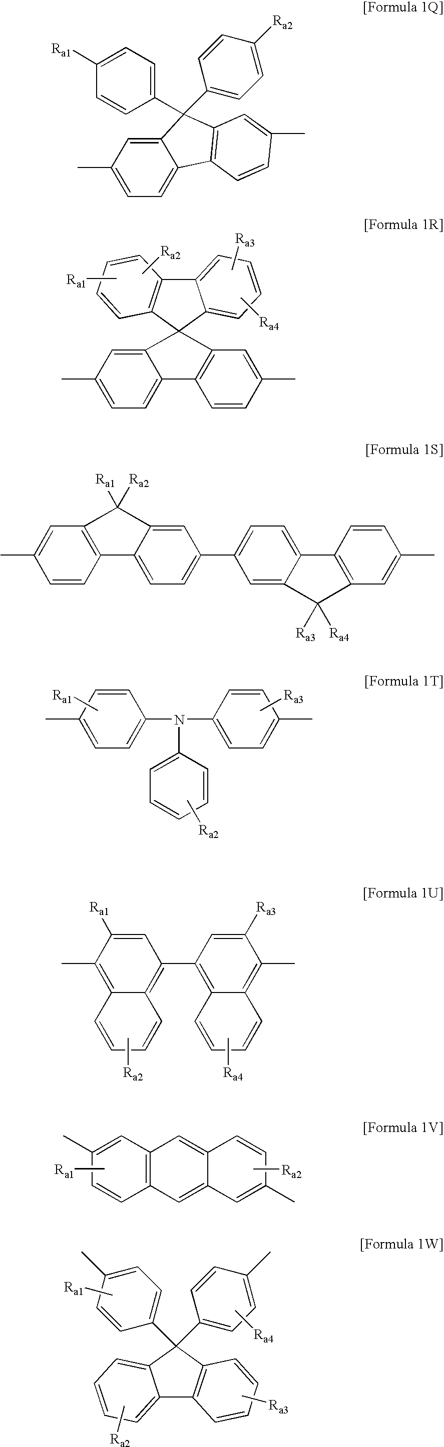

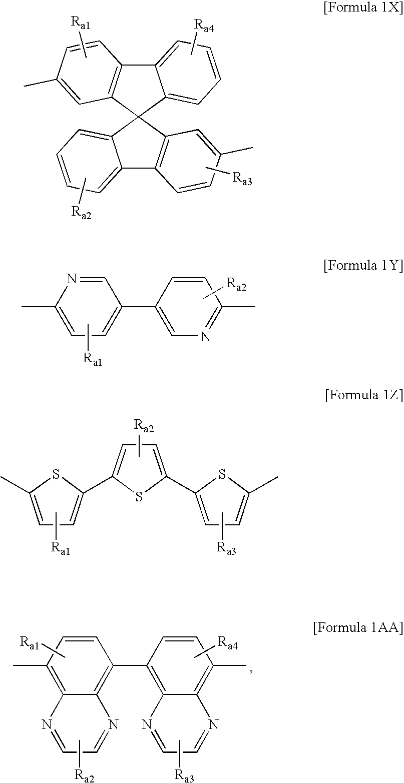

where Rₐ₁, Rₐ₂, Rₐ₃, and Rₐ₄ are each an ionic group, hydrogen, a substituted or unsubstituted C1-C12 alkyl group, a substituted or unsubstituted C1-C12 alkoxy group, a substituted or unsubstituted C6-C20 aryl group, or —N(R′)(R″)(R′ and R″ are each hydrogen, or a substituted or unsubstituted C1-C12 alkyl group).

When the conjugated compound is substituted with an ionic group composed of an anionic group and a cationic group, the anionic group may be PO₃²⁻, SO₃⁻, COO⁻, I⁻, or CH₃COO⁻, and the cationic group (i.e., the counter ion of the anionic group) may be a metal ion such as Na⁺, K⁺, Li⁺, Mg⁺², Zn⁺², and Al⁺³; or an organic ion such as H⁺, NH₃⁺, and CH₃(—CH₂—)ₙO⁺ (n is a natural number from 1 to 50).

According to an embodiment of the present invention, in the compound represented by Formula 1 in the present invention, m=1, n=0, and p=0, and the compound represented by Formula 1 is a fluorocarbon polymer, and more preferably a perfluorinated compound.

Preferably, examples of the compound represented by Formula 1 in the present invention include compounds represented by Formulas 2 through 12:

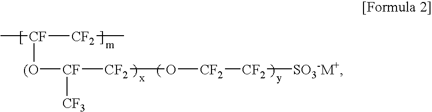

where m is in the range of 1 to 10,000,000, and x and y are each in the range of 0 to 10, M⁺ is Na⁺, K⁺, Li⁺, H⁺, CH₃(CH₂)ₙNH₃⁺ (n is an integer from 0 through 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

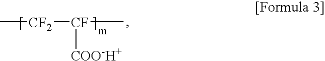

where m is in the range from 1 to 10,000,000.

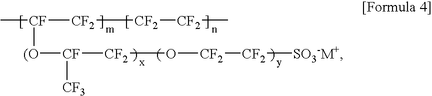

where 0<m≦10,000,000, 0≦n<10,000,000, and x and y are each in the range of 0 to 20, M⁺ is Na⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

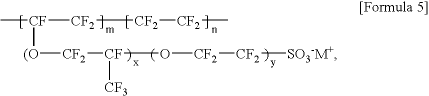

where 0<m≦10,000,000, 0≦n<10,000,000, and x and y are each in the range of 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

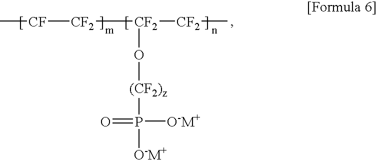

where 0<m≦10,000,000, 0≦n<10,000,000, z is an integer from 0 through 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

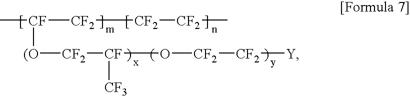

where 0<m≦10,000,000, 0≦n<10,000,000, and x and y are each in the range of 0 to 20, Y is one selected from —COO⁻M⁺, —SO₃⁻NHSO₂CF₃⁺, and —PO₃²⁻(M⁺)₂, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

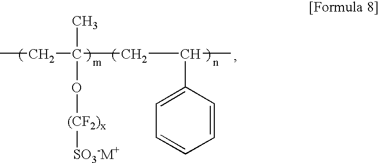

where 0<m≦10,000,000, 0≦n<10,000,000, and x and y are each in the range of 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

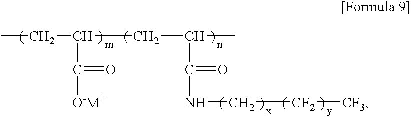

where 0<m≦10,000,000, 0≦n<10,000,000, and x and y are each in the range of 0 to 20, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

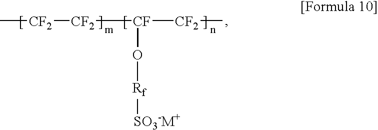

where 0≦m<10,000,000, 0<n≦10,000,000, R_{f}=—CF₂)_{z}— (z is 1 or an integer from 3 to 50), —(CF₂CF₂O)_{z}CF₂CF₂— (z is an integer from 1 to 50), —(CF₂CF₂CF₂O)_{z}CF₂CF₂— (z is an integer from 1 to 50), M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

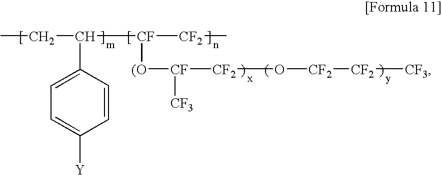

where 0≦m≦10,000,000, 0<n≦10,000,000, x and y are each in the range of 0 to 20, Y is one selected from the group consisting of —SO₃^{-M}⁺, —COO⁻M⁺, —SO₃⁻NHSO₂CF3⁺, and —PO₃²⁻(M⁺)₂, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

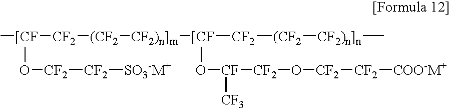

where 0≦m<10,000,000, 0<n≦10,000,000, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

The content of the compound represented by Formula 1 in the organic layer in the present invention is preferably 10 to 5,000 parts by weight based on 100 parts by weight of the conjugated compound, preferably 100 to 3,000 parts by weight. When the content of the compound is less than 10 parts by weight, the content of the compound represented by Formula 1 is not sufficient to form a gradient of the concentration, and when the content of the compound is greater than 5,000 parts by weight, the content of the conjugated polymer is not sufficient to form a gradient of the concentration.

As described above, when the organic layer including the conjugated compound and the compound represented by Formula 1 is formed through a single solution process by self organization, the compound represented by Formula 1 does not have good miscibility with the conjugated compound because the compound represented by Formula 1 is substituted with at least one fluorine atom and thus has hydrophobicity or low surface energy compared to the conjugated compound. Accordingly, at least one of the conjugated compound and the compound represented by Formula 1 can have a concentration gradient in the direction from the first electrode to the second electrode, and more preferably, the concentration of the compound represented by Formula 1 increases in the direction from the first electrode to the second electrode.

The organic layer according to the current embodiment of the present invention may further include a compound represented by Formula 13:

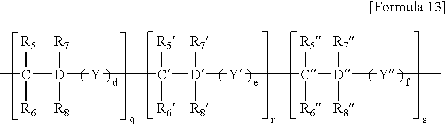

where 0<q<10,000,000, 0≦r<10,000,000, 0≦s<10,000,000, 0≦d≦20, 0≦e≦20, and 0≦f≦20;

C, D, C′, D′, C″, and D″ are each independently selected from the group consisting of C, Si, Ge, Sn, and Pb;

R₅, R₆, R₇, R₈, R₅′, R₆′, R₇′, R₈′, R₅″, R₆″, R₇″, and R₈″ are each independently selected from the group consisting of hydrogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group, and a substituted or unsubstituted C6-C30 heteroarylester group, and if substituted, not substituted with fluorine (that is, the substituent of the substituted 1 group is not fluorine);

at least one of R₆, R₇, R₈, R₉, R₆′, R₇′, R₈′, and R₉′ is an ionic group or includes an ionic group; and

Y, Y′, and Y″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, and if substituted, not substituted with fluorine (that is, the substituent of the substituted group is not fluorine).

Examples of the ionic group of Formula 13 include a cationic group selected from the group consisting of PO₃², SO₃⁻, COO⁻, I⁻, CH₃COO⁻, and an anionic group that is selected from the group consisting of a metal ion such as Na⁺, K⁺, Li⁺, Mg⁺², Zn⁺², and Al⁺³, and an organic ion such as H⁺, NH₃⁺, and CH₃(—CH₂—)ₙO⁺ (n is a natural number from 1 to 50), and forms a pair with the cationic group.

In the organic layer according to the current embodiment of the present invention, the amount of the compound represented by Formula 13 may be 10 to 5,000 parts by weight based on 100 parts by weight of the conjugated compound, preferably 100 to 3,000 parts by weight. When the amount is less than 10 parts by weight, the addition of Formula 13 does not have effect, and when the amount is greater than 5,000 parts by weight, the conductivity decreases rapidly.

As described above, an organic layer including the conjugated compound, a compound represented by Formula 1, and a compound represented by Formula 13 is formed through a single solution process by self organization, and as a result, at least one of the compounds represented by Formula 1 and Formula 13 can have a concentration gradient that increases in the direction from the first electrode to the second electrode, and more preferably, the concentration of the compound represented by Formula 1 increases in the direction from the first electrode to the second electrode.

This is because the compound represented by Formula 1 is substituted with

where 0<q≦10,000,000, 0≦r<10,000,000, 0≦s<10,000,000, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

The unsubstituted alkyl group, which is one of the substitution groups used in the present invention, is straight or branched and may include methyl, ethyl, propyl, isobutyl, sec-butyl, tert-butyl, pentyl, iso-amyl, hexyl, and at least one of the hydrogen atoms included in the alkyl group can be substituted with a halogen atom, a hydroxyl group, a nitro group, a cyano group, a substituted or unsubstituted amino group(—NH₂, —NH(R), —N(R′)(R″), R′, and R″ are each C1-C10 alkyl group), an amidino group, hydrazine, or a hydrazone group, a carboxyl group, a sulfonic acid group, phosphoric acid group, a C1-C20 alkyl group, a C1-C20 halogenized alkyl group, a C1-C20 alkenyl group, a C1-C20 alkynyl group, a C1-C20 heteroalkyl group, a C6-C20 aryl group, a C6-C20 arylalkyl group, a C6-C20 heteroaryl group, or a C6-C20 heteroarylalkyl group.

The heteroalkyl group used in the present invention refers to at least one carbon atom in the main chain of the alkyl group, preferably, a C1-C5 carbon atom substituted with a hetero atom such as an oxygen atom, a sulfur atom, a nitrogen atom, a phosphorus atom, etc.

The aryl group used in the present invention refers to a carbocyclic aromatic system including at least one aromatic ring, and the rings are attached together using a pendant method, or are fused. Examples of the aryl group include an aromatic group such as phenyl, naphthyl, tetrahydronaphthyl, etc., and at least one hydrogen atom among the aryl group can also be substituted with the same substitution group as in the case of the alkyl group.

The heteroaryl group used in the present invention, which is a substitution group, refers to a C5-C30 cyclic aromatic system that includes one through three hetero atoms selected from N, O, P, and S, wherein the rest of the ring atoms are C, and the rings are attached together using a pendant method, or are fused. At least one of a plurality of hydrogen atoms among the heteroaryl group can be substituted with the same substitution group as in the case of the alkyl group.

The alkoxy group, which is one of the substitution groups used in the present invention, refers to a radical-O-alkyl, and the alkyl here is as defined above. Examples of the alkoxy include methoxy, ethoxy, propoxy, isobutyloxy, sec-butyloxy, at least one fluorine atom and thus has low surface energy and decreased miscibility compared to the compound represented by Formula 13.

In detail, examples of the compound represented by Formula 13 include Formulas 14 through 16:

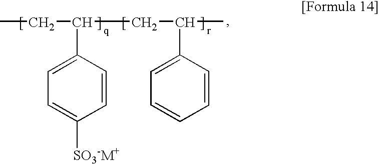

where 0<q≦10,000,000, 0≦r<10,000,000, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50).

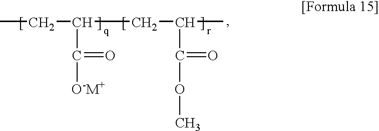

where 0<q≦10,000,000, 0≦r<10,000,000, M⁺ is Na⁺, K⁺, Li⁺, H⁺, CH₃(CH₂)ₙNH₃⁺ (n is an integer from 0 to 50), NH₄⁺, NH₂⁺, NHSO₂CF₃⁺, CHO⁺, C₂H₅OH⁺, CH₃OH⁺, or RCHO⁺ (R is an alkyl group, that is, CH₃(CH₂)ₙ⁻; n is an integer from 0 to 50). 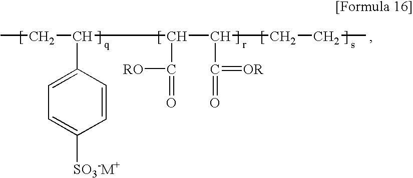
pentyloxy, iso-amyloxy, hexyl oxy, etc., and at least one hydrogen atom among the alkoxy group can be substituted with the same substitution group as in the case of the alkyl group.

The heteroalkoxy group, which is one of the substitution groups used in the present invention, is substantially the same as the alkoxy group, except that O, S, or N can be present in the alkyl chain. Examples of the heteroalkoxy group include CH₃CH₂OCH₂CH₂O—, C₄H₉OCH₂CH₂OCH₂CH₂O—, and CH₃O(CH₂CH₂O)ₙH.

The arylalkyl group, which is one of the substitution groups used in the present invention, refers to an aryl group as defined above, in which a portion of the hydrogen atom is substituted with a radical such as methyl, ethyl, propyl, etc. Examples of the arylalkyl group are benzyl, phenylethyl, etc. At least one hydrogen atom among the arylalkyl group can be substituted with the same substitution group as in the case of the alkyl group.

The heteroarylalkyl group used in the present invention refers to a heteroaryl group in which a portion of the hydrogen atom is substituted with a lower alkyl group, and the heteroaryl group among the heteroarylalkyl group is as defined above. At least one hydrogen atom among the heteroarylalkyl group can be substituted with the same substitution group.

The aryloxy group used in the present invention refers to radical-O-aryl, and the aryl is defined as above. Examples of the aryloxy group include phenoxy, naphthoxy, anthracenyl oxy, phenanthrenyl oxy, fluorenyl oxy, indenyl oxy, etc., and at least one hydrogen atom among the aryloxy group can be substituted with the same substitution group as in the case of the alkyl group.

The heteroaryloxy group used in the present invention refers to radical-O-heteroaryl, and the heteroaryl is as defined above.

Examples of the heteroaryloxy group include benzyl oxy, phenylethyloxy, etc., and at least one hydrogen atom among the heteroaryloxy group can be substituted with the same substitution group as in the case of the alkyl group.

The cycloalkyl group used in the present invention refers to a C5-C30 univalent monocyclic system. At least one hydrogen atom in the cycloalkyl group can be substituted with the same substitution group as in the case of the alkyl group.

The heterocycloalkyl group used in the present invention refers to a C5-30 univalent monocyclic system including one to three hetero atoms selected from N, O, P, and S, wherein the rest of the rings are C atoms. At least one of the hydrogen atoms in the cycloalkyl group can be substituted with the same substitution group as in the case of the alkyl group.

The alkylester group used in the present invention refers to a functional group in which an alkyl group and an ester group are combined, and the alkyl group is as defined above.

The heteroalkylester group used in the present invention refers to a functional group in which a heteroalkyl group and an ester group are combined, and the heteroalkyl group is as defined above.

The arylester group used in the present invention refers to a functional group in which an aryl group and an ester group are combined, and the aryl group is as defined above.

The heteroarylester group used in the present invention refers to a functional group in which a heteroaryl group and an ester group are combined, and the heteroaryl group is as defined above.

The amino group used in the present invention refers to —NH₂, —NH(R), or —N(R′)(R″), and R′ and R″ are each C1-C10 alkyl groups.

The halogen used in the present invention may be fluorine, chlorine, bromine, iodine, or astatine, preferably fluorine.

Also, the organic layer may further include a physical and/or chemical cross linking agent to improve the cross linking ability of the conjugated compound with the compound represented by Formula 1 and/or 13.

The physical cross-linking agent cross-links the polymer chains without chemical bonding, and may be a small molecule compound or a polymer including a hydroxyl group (—OH). Examples of the low-molecular compound include glycerol and butanol, and examples of the polymer include polyvinyl alcohol, polyvinylphenol, polyethylene glycol, etc. Polyethyleneimine, polyvinylpyrrolidone, etc. can also be used.

The content of the physical cross-linking agent is preferably 0.001 to 5 parts by weight based on 100 parts by weight of the organic material solution for forming an organic layer, more preferably 0.1 to 3 parts by weight. When the content of the physical cross-linking agent is less than 0.001 parts by weight, the physical cross linking agent cannot sufficiently cross-link, and when the content of the physical cross-linking agent is greater than 5 parts by weight, the thin film morphology of the organic layer is not satisfactory.

Also, the chemical cross-linking agent is a chemical material which cross-links chemically, can be in-situ polymerized, and can form an interpenetrating polymer network. Examples of the chemical cross-linking agent include silane material such as tetraethyloxysilane (TEOS). Polyaziridine, melamine, epoxy material, and so forth can also be used.

The content of the chemical cross-linking agent may be 0.001 to 50 parts by weight based on 100 parts by weight of the organic material solution for forming an organic layer, preferably 1 to 10 parts by weight. When the content of the chemical cross-linking agent is less than 0.001 parts by weight, the chemical cross-linking agent cannot cross-link sufficiently, and when the content of the chemical cross-linking agent is greater than 50 parts by weight, the conductivity of the organic layer decreases rapidly.

The organic layer according to the current embodiment of the present invention may further include metal nanoparticles. The metal nanoparticles can improve the conductivity of the organic layer.

Preferably, the metal nanoparticles may be at least one type of metal nanoparticles selected from the group consisting of Au, Ag, Cu, Pd, and Pt nanoparticles. The metal nanoparticles may have preferably an average diameter of 5 to 20 nm. When the average diameter of the metal nanoparticles is less than 5 nm, the nanoparticles are likely to agglomerate together easily, and when the average diameter of the metal nanoparticles is greater than 20 nm, the surface smoothness of the organic layer cannot be controlled.

Also, the organic layer in the present invention may further include inorganic nanoparticles. When an organic layer including the organic nanoparticles is formed, the inorganic nanoparticles are dispersed in the organic layer to facilitate conductivity in the networks between the conjugated compound or to strengthen the networks.

Preferably, the inorganic nanoparticles may be at least one type of inorganic nanoparticles selected from the group consisting of SiO₂ and TiO₂ nanoparticles. The inorganic nanoparticles may have preferably an average diameter of 5 to 100 nm. When the diameter of the inorganic nanoparticles is less than 5 nm, the nanoparticles are likely to agglomerate together easily, and when the diameter of the inorganic nanoparticles is greater than 100 nm, the surface smoothness of the film cannot be controlled.

Hereinafter, an organic light emitting device employing an organic layer including an organic material of the present invention, and a method of manufacturing the same will be described, according to embodiments of the present invention.

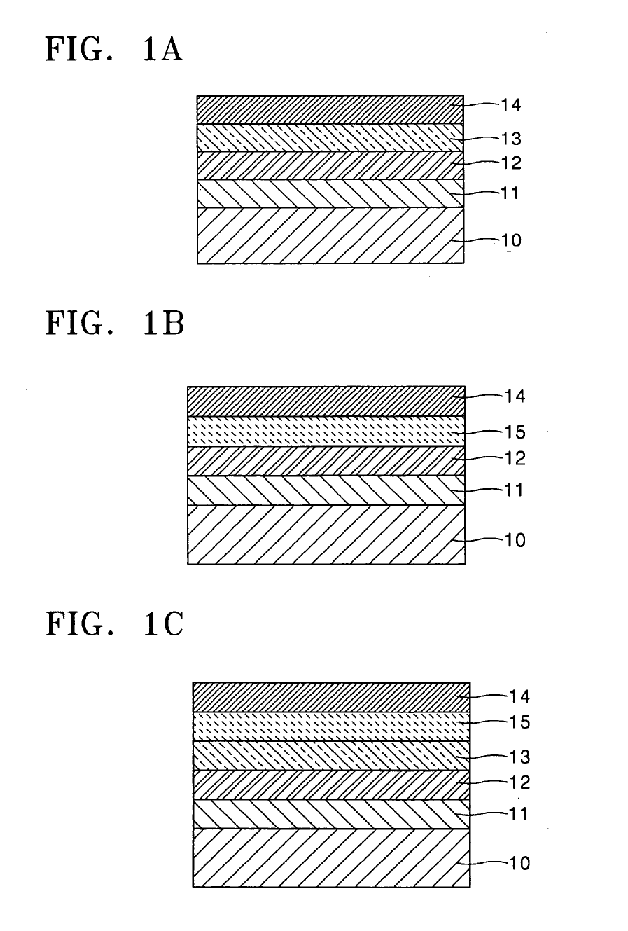

FIG. 1A through 1D illustrate laminated structures of an organic light emitting device according to embodiments of the present invention.

In the organic light emitting device in FIG. 1A, an emissive layer 12 is stacked on a first electrode 10, a hole injection layer (HIL) 11 (also referred to as “buffer layer”) including the organic material of the present invention is stacked between the first electrode 10 and the emissive layer 12, a hole blocking layer (HBL) 13 is stacked on the emissive layer 12, and a second electrode 14 is formed on the HBL 13.

The organic light emitting device in FIG. 1B has the same laminated structure as in FIG. 1A, except that an electron transporting layer (ETL) 15 is formed instead of the HBL 13 on the emissive layer 12.

The organic light emitting device of FIG. 1C has the same laminated structure as in FIG. 1A, except that a double-layer film in which the HBL 13 and the ETL 15 are sequentially stacked instead of the HBL 13 on the emissive layer 12.

The organic light emitting device of FIG. 1D has the same structure as the organic light emitting device of FIG. 1C, except that a hole transporting layer 16 is further formed between a hole injection layer 11 and an emissive layer 12. The hole transporting layer 16 suppresses penetration of impurities from the hole injection layer 11 to the emissive layer 12.

The organic light emitting devices having laminated structures as in FIGS. 1A through 1D as described above can be manufactured using ordinary methods, and the methods are not particularly limited.

Hereinafter, a method of manufacturing the organic light emitting device according to an embodiment of the present invention will be described.

First, a patterned first electrode 10 is formed on a substrate (not shown). The substrate may be a substrate used in conventional organic light emitting devices, for example, a glass substrate or a transparent plastic substrate, has a smooth surface, can be treated easily, and is waterproof. The thickness of the substrate may be 0.3 to 1.1 mm.

A material forming the first electrode 10 is not limited. When the first electrode 10 is an anode, the anode is formed of a conductive metal or an oxide thereof with which holes can be easily injected, and examples of the material include indium tin oxide (ITO), indium zinc oxide (IZO), nickel (Ni), platinum (Pt), gold (Au), iridium (Ir), etc.

The substrate, on which the first electrode 10 is formed, is cleansed, and then is treated with ozone. Organic solvents such as deionized (DI) water, acetone and isopropanol (IPA) may be used to cleanse the substrate.

A hole injection layer 11 including an organic material of the present invention is formed on the first electrode 10 of the cleansed substrate. When such a hole injection layer 11 is formed, contact resistance between the first electrode 10 and an emissive layer 12 is reduced, and hole injection and transportation abilities with respect to the emissive layer 12 are improved, thereby improving the driving voltage of the organic light emitting device and the lifetime of the organic light emitting device in general.

A material forming the hole injection layer 11 is not limited. Examples of the material forming the hole injection layer 11 include copper phthalocyanine (CuPc), starburst-type amine such as TCTA, m-MTDATA, H1406 (available from Idemitsu Corporation), soluble conducting polymer such as polyaniline/Dodecylbenzenesulfonic acid (Pani/DBSA) or poly(3,4-ethylenedioxythiophene)/Poly(4-styrenesulfonate) (PEDOT/PSS), polyaniline/Camphor sulfonic acid (Pani/CSA) or (polyaniline)/Poly(4-styrenesulfonate) (PANI/PSS), etc.

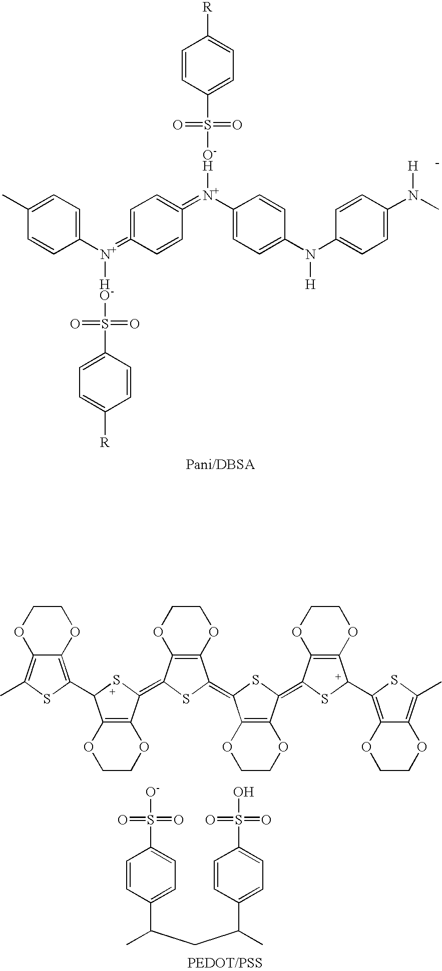

The hole injection layer 11 is formed by spin-coating a composition for forming a hole injection layer, which is prepared by dissolving the organic material in a solvent, on the first electrode 10, and then drying the composition. The composition for forming the hole injection layer is a solution prepared by diluting the organic material of the present invention using an organic solvent such as water, alcohol, dimethylformamide, and dimethyl sulfoxide dichloroethane, etc. in a ratio of 0.5 to 10 weight %.

Any material that can dissolve the organic material can be used, and examples of the solvents are organic solvents such as water, alcohol, dimethylformamide (DMF), toluene, xylene, chlorobenzene, etc.

The thickness of the hole injection layer 11 may be 5 to 1,000 nm, preferably 10 to 100 nm. The thickness of the hole injection layer 11 according to the current embodiment of the present invention may be 50 nm. When the thickness of the hole injection layer 11 is less than 5 nm, it is too thin to properly inject holes, and when the thickness of the hole injection layer 11 is greater than 1,000 nm, the degree of light transmission may decrease.

The emissive layer 12 is formed on the hole injection layer 11. The material forming the emissive layer 12 is not limited. Examples of the material forming the emissive layer 12 include oxadiazole dimer dyes (Bis-DAPOXP), spiro compounds (Spiro-DPVBi, Spiro-6P), triarylamine compounds, bis(styryl)amine (DPVBi, DSA), Compound (A), bis[2-(4,6-difluorophenyl)pyridinato-N,C^{2′}] iridium picolinate (Flrpic), CzTT, Anthracene, 1,1,4,4-tetraphenyl-1,3-butadiene (TPB), 1,2,3,4,5-pentaphenyl-1,3-cyclopentadiene (PPCP), DST, TPA, OXD-4, BBOT, AZM-Zn, etc. which are blue materials, Coumarin 6, C545T, quinacridone, tris(2-phenylpyridine)-iridium (Ir(ppy)₃), etc., which are green materials, and DCM1, DCM2, Eu(thenoyltrifluoroacetone)₃ (Eu(TTA)₃), butyl-6-(1,1,7,7-tetramethyljulolidyl-9-enyl)-4H-pyran (DCJTB), etc., which are red materials. In addition, examples of the polymer light-emitting material include polymers such as phenylene, phenylene vinylene, thiophene, fluorene, and spiro-fluorene-based polymers and aromatic compounds containing nitrogen, but are not limited thereto.

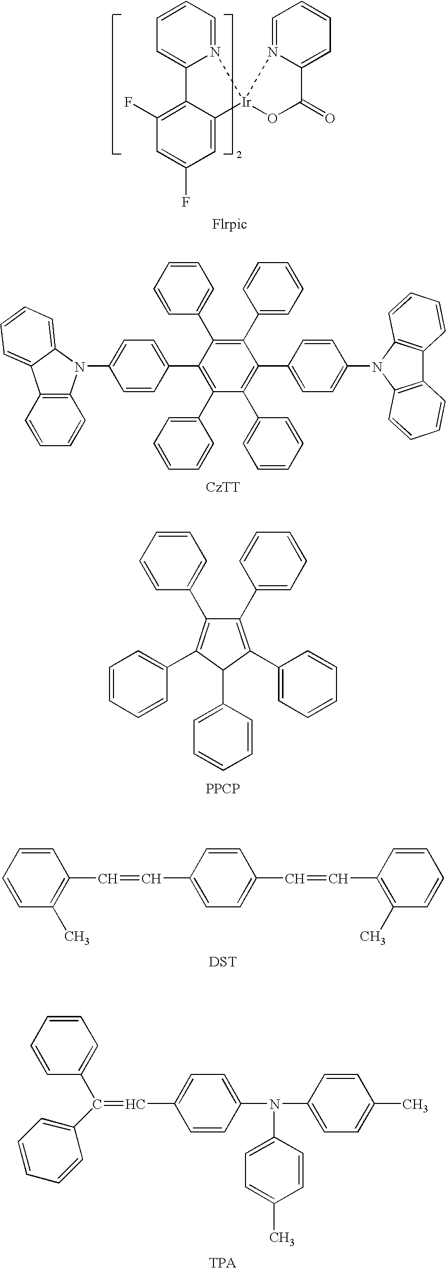

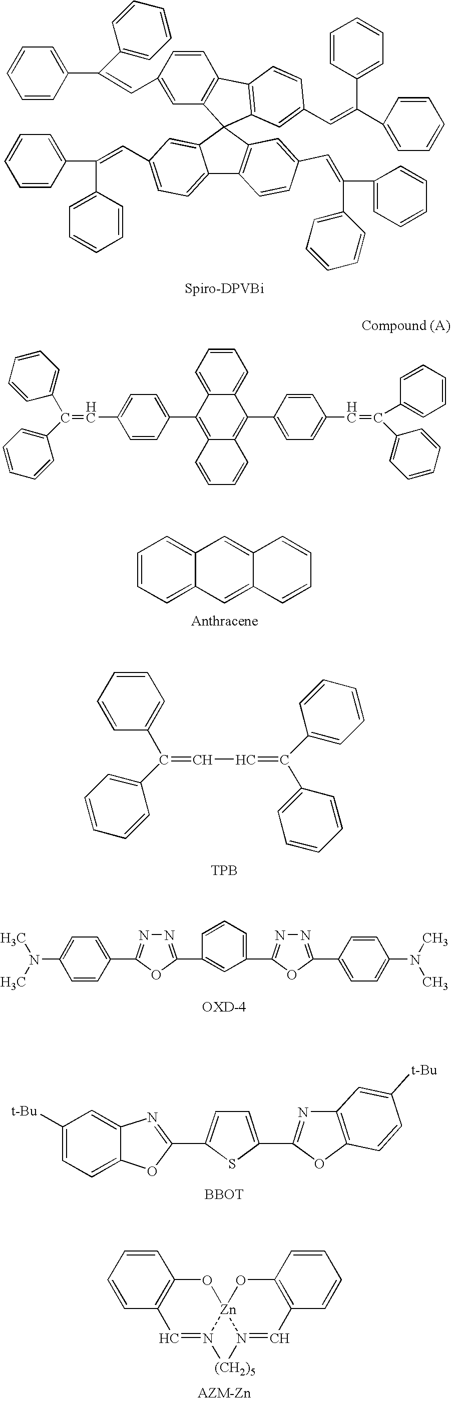

The thickness of the emissive layer 12 may be 10 nm to 500 nm, preferably 50 nm to 120 nm. Here, the thickness of a blue emissive layer may be 70 nm. When the thickness of the emissive layer 12 is less than 10 nm, leakage current increases, thus decreasing efficiency, and when the thickness of the emissive layer 12 is greater than 500 nm, the driving voltage of the organic light emitting device increases by a larger unit.

A dopant may be further added to the material for forming the emissive layer 12 in some cases. The content of the dopant may vary according to the material for forming the emissive layer 12, but may be 1 to 80 parts by weight based on 100 parts by weight of the material for forming the emissive layer 12 (the total weight of the host and the dopant). If the content of the dopant is outside the above range, the luminescence of the organic light emitting device decreases. Examples of the dopant include arylamine, a peryl compound, a pyrrole compound, a hydrazone compound, a carbazole compound, a stilbene compound, a starburst compound, an oxadiazole compound, etc.

A hole transporting layer 16 may be optionally formed between the hole injection layer 11 and the emissive layer 12.

The material for forming the hole transporting layer 16 is not limited, and may be a material including at least one selected from the group consisting of a carbazol group transporting holes and/or a compound having an arylamine group, a phthalocyanine compound and a triphenylene derivative. In detail, the hole transporting layer 16 may be formed of at least one compound of the group consisting of 1,3,5-tri-carbazoyl benzene, 4,4′-bis carbazolyl biphenyl, poly vinyl carbazole, M-bis carbazolyl phenyl, 4,4′-bis carbazolyl-2,2′-dimethyl biphenyl, 4,4′,4″-tri(N-carbazolyl) triphenylamine, 1,3,5-tri (2-carbazolyl phenyl) benzene, 1,3,5-tris (2-carbazolyl-5-methoxy phenyl) benzene, bis (4-carbazolyl phenyl) silane, N,N′-bis (3-methyl phenyl)-N,N′-diphenyl-[1,1-biphenyl]-4,4′diamine (TPD), N,N′-di (naphthalene-1-il)-N,N′-diphenylbenzidine (a-NPD), N,N′-diphenyl-N,N′-bis (1-naphthyl)-(1,1′-biphenyl)-4,4′-diamine (NPB), IDE 320 (Idemitsu Corporation), poly (9,9-dioctylfluorene-co-N-(4-butylphenyl) diphenylamine) (poly (9,9-dioctylfluorene-co-N-(4-butylphenyl)diphenylamine) (TFB), and, poly (9,9-dioctylfluorene-co-bis-N,N-phenyl-1,4-phenylene diamine (poly (9,9-dioctylfluorene-co-bis-(4-butylphenyl-bis-N,N-phenyl-1,4-phenylenediamin) (PFB), but is not limited thereto.

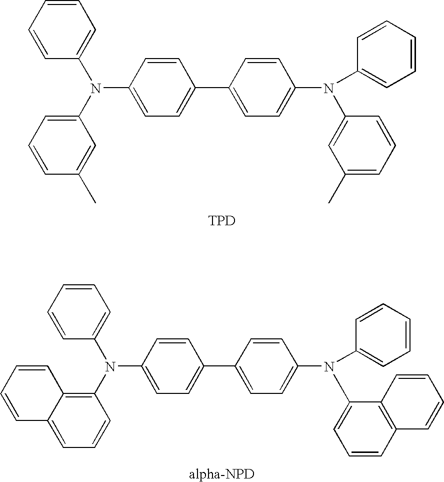

The hole transporting layer 16 has a thickness of 1 to 100 nm, preferably 5 to 50 nm. According to the current embodiment of the present invention, the thickness of the hole transporting layer 16 is preferably less than 30 nm. When the thickness of the hole transporting layer 16 is less than 1 nm, it is too thin and thus hole transporting ability is decreased. When the thickness of the hole transporting layer 16 is greater than 100 nm, the driving voltage of the organic light emitting device may increase.

In the field of OLEDs, one material can be used to form a hole injection layer or a hole transporting layer, and thus it is difficult to define the function of the material by the structure of the material. In the case of a composition in which a conducting copolymer such as PEDOT and PANI is doped with an organic acid (e.g., PSS), the composition is deposited on ITO and thus the material is usually called a hole injection layer, but sometimes a hole transporting layer by researchers according to their custom and device structures because the material has both the good hole injection and transporting properties. For example, CuPc is deposited on ITO and does not have great hole transporting ability, and thus is mostly used as a hole injection layer because additional transporting layer is necessary. When aryl amine materials in spite of the good hole transporting property are deposited on ITO and they are advantageous for hole injection in consideration of the work function of ITO and the HOMO value of the emissive layer, they are called a hole injection layer and when an excellent hole transporting layer is additionally deposited on the top of the hole injection layer, it is called a hole transporting layer in general.

A hole blocking layer 13 and/or an electron transporting layer 15 are formed on the emissive layer 12 using a deposition or spin-coating method. Here, the hole blocking layer 13 blocks excitons generated in the luminescent material from moving toward the electron transporting layer 15 or blocks holes from moving to the electron transporting layer 15.

Examples of the material for forming the hole blocking layer 13 include a phenanthrolines compound (example: BCP, available from UDC), an imidazole compound, a triazole compound, an oxadiazole compound (example: PBD), an aluminum complex (available from UDC), aluminum(III)bis(2-methyl-8-quinolinato)₄-phenylphenolate (BAIq) represented by the formula below.

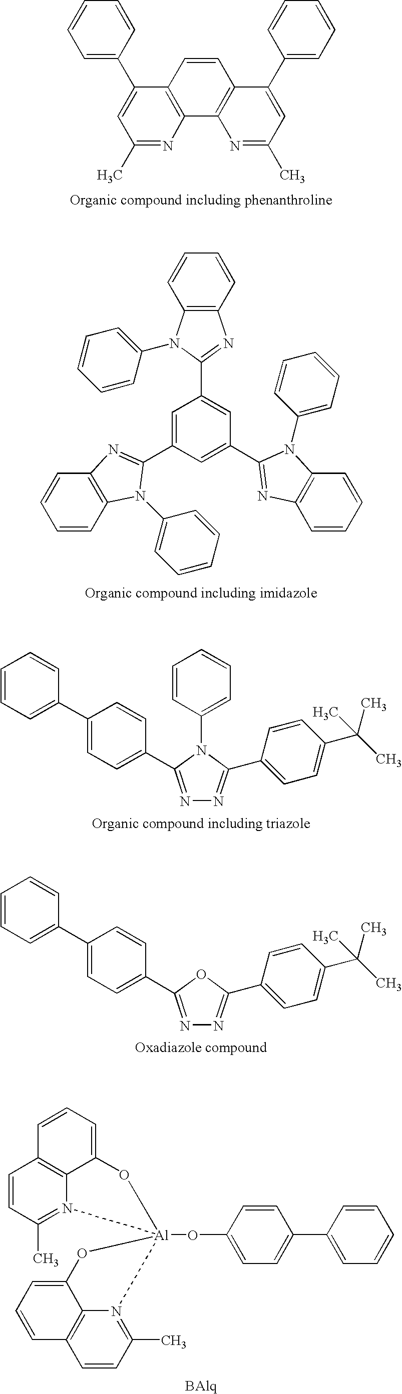

Examples of the material for forming the electron transporting layer 15 include an oxazole compound, an isooxazole compound, a triazole compound, an isothiazole compound, an oxadiazole compound, a thiadiazole compound, a perylene compound, an aluminum complex (Alq₃(tris(8-quinolinolato)-aluminium), BAlq, SAlq, Almq₃, gallium complex(e.g., Gaq′2OPiv, Gaq′2OAc, 2(Gaq′2)), etc.

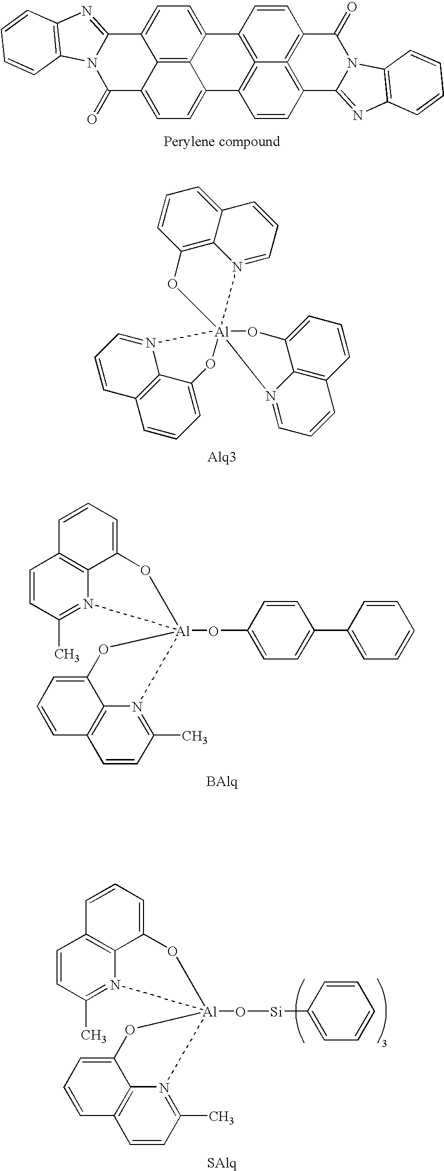

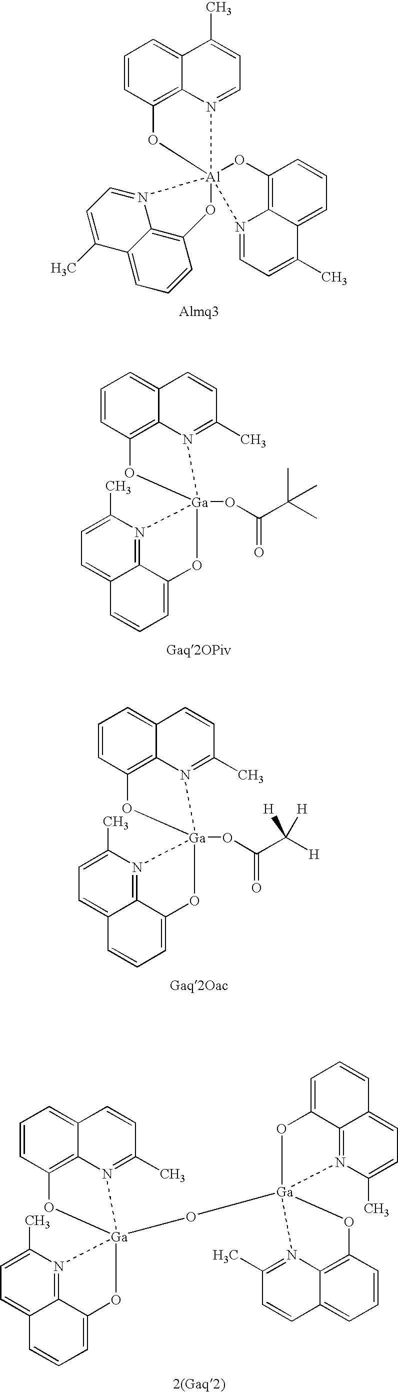

The thickness of the hole blocking layer 13 may be 5 nm to 100 nm, and the thickness of the electron transporting layer 15 may be 5 nm to 100 nm. When the thicknesses of the hole blocking layer 13 and the electron transporting layer 15 are outside these ranges, the hole blocking capability and the electron transporting ability are not desirable.

Then a second electrode 14 is formed on the resultant composition, and is encapsulated to complete the formation of the organic light emitting device according to the current embodiment of the present invention.

The material for forming the second electrode 14 is not limited, and a metal having a small work function, that is, Li, Cs, Ba, Ca, Ca/Al, LiF/Ca, LiF/Al, BaF₂/Ca, Mg, Ag, Al, an alloy thereof, or a multi-layer structure thereof may be used. The thickness of the second electrode 14 may be 50 through 3,000 Å.

The organic light emitting device according to the current embodiment of the present invention can be manufactured without special apparatus or method, and can be manufactured using a conventional method.

Hereinafter, the present invention will be described in more detail with reference to the following examples. However, these examples are not intended to limit the scope of the invention.

Manufacturing Example 1: Manufacture of Organic Material Solution

1) Synthesis of Formula 14 (polystyrene sulfonate: PSS)

Polystyrene having a weight average molecule amount of 230,000 (number average molecule amount 140,000) was purchased from Sigma-Aldrich Co. Sulfonation of the polystyrene was performed using acetyl sulfate as a sulfonation agent in 1,2-dichroroethan solvent at 50 degrees. Sulfonate polymer was obtained by steam stripping, and was dried in a vacuum oven at 60 degrees for two days to remove the remaining solvent. The amount of the sulfonate of the polymer corresponds to 95 mol % of polystyrene main chain.

2) Synthesis of Conjugated Compound (PEDOT)/PSS

Then the synthesized PSS was dissolved in water, and a conjugated compound PEDOT was polymerized in water, methanol, or DMF as in the state of this medium using a well known synthesis method disclosed [Greonendaal et al. Advanced Materials, Vol. 12, p 481, 2000] to obtain PEDOT/PSS.

3) Synthesis of Formula 5 (PFI)

A compound (PFI) having a structure of Formula 5 and dissolved in a mixed solvent of 4.5:5.5 of water and alcohol (2-propanol) in 5 wt % was purchased from Sigma-Aldrich Co.

4) Manufacture of Organic Material Solution

Then 100 parts by weight of PEDOT, 600 parts by weight of PSS, and 158.5 parts by weight of PFI were mixed in a mixed solution of water and alcohol (water:alcohol=60:40), that is, the solvent, to 1.35 wt % to prepare an organic material solution.

Manufacturing Example 2: Manufacture of Organic Material Solution

An organic material solution was prepared as in Manufacturing Example 1, except that 317 parts by weight of Formula 5 (PFI) was added.

Manufacturing Example 3: Manufacture of Organic Material Solution

An organic material solution was prepared as in Manufacturing Example 1, except that 634.1 parts by weight of Formula 5 (PFI) was added.

Manufacturing Example 4: Manufacture of Organic Material Solution

An organic material solution was prepared as in Manufacturing Example 1, except that 1268.1 parts by weight of Formula 5 (PFI) was added.

Manufacturing Example 5: Manufacture of Organic Material Solution

An organic material solution was prepared as in Manufacture Example 1, except that 2536.2 parts by weight of Formula 5 (PFI) was added.

Comparative Manufacturing Example: Organic Material Solution Manufacture

An organic material solution was prepared as in Manufacturing Example 1, except that Formula 5 (PFI) was not added.

The work function of the organic material solutions of Manufacturing Examples 3 through 5 and Comparative Manufacturing Example was measured using a surface analyzer (Model AC2, available from Riken Keiki Co., Ltd) in an air atmosphere and the results are shown in Table 1 below.

TABLE 1
Evaluation of work function of organic material solution

| | PEDOT:PSS:PFI | Work function (eV) |
|---|---|---|
| Sample | (parts by weight) | (AC2) |
| Comparative | 100:600:0 | 5.20 |
| Manufacturing | | |
| Example | | |
| Manufacturing | 100:600:158.5 | 5.55 |
| Example 1 | | |
| Manufacturing | 100:600:317 | 5.63 |
| Example 2 | | |
| Manufacturing | 100:600:634.1 | 5.72 |
| Example 3 | | |
| Manufacturing | 100:600:1268.1 | 5.79 |
| Example 4 | | |
| Manufacturing | 100:600:2536.2 | 5.95 |
| Example 5 | | |

As can be seen from Table 1, the work function of the organic material increases as the content of PFI, that is, Formula 5 increases, and as a result, a solution having a high work function (−5.55 through 5.95 eV) was obtained.

Also, in Table 2, dipole moment, ionization potential (IP), and deprotonation energy of hetero fluorinated carbon sulfonic acid and hydrocarbon sulfonic acid are compared.

That is, when the sulfonic acid is deprotonized, the IP level calculated in hetero fluorinated carbon sulfonic acid is smaller than the corresponding hetero hydrocarbon acid. This is because the electron absorption of fluorine atoms makes it difficult for the fluorine carbon molecules to oxidize more than the corresponding carbon hydrogen. Thus it is evident that the polymer having a fluorine carbon sulfonic acid such as PFI has a lower IP level than polystyrene sulfonic acid.

TABLE 2
Calculated dipole moment, ionization potential (IP), and deprotonation energy (DP) of the terminal
group obtained using density-functional theory calculations (using Gaussian 98 program).

| | Dipole | | | |
|---|---|---|---|---|
| | (neutral) | Dipole(deprotonation) | | |
| Terminal group | (Debye) | (Debye) | IP(eV) | DP(kcal/mol) |
| CH₂CH₂SO₃H | 3.395 | 4.935 | −8.287 | 336.3 |
| CH₃—O—CH₂CH₂SO₃H | 2.681 | 8.154 | −7.424 | 332.8 |
| (CH₃)₂CH—O—CH₂—(CH₃)CH—O—CH₂CH₂SO₃H | 3.807 | 19.522 | −6.943 | 332.6 |
| CF₂CF₂SO₃H | 2.800 | 6.248 | −9.316 | 316.0 |
| CF₃—O—CF₂CF₂SO₃H | 2.578 | 10.107 | −9.248 | 314.4 |
| (CF₃)₂CF—O—CF₂—(CF₃)CF—O—CF₂CF₂SO₃H | 2.719 | 21.940 | −9.264 | 314.3 |
| Ph-SO₃H | 4.361 | 8.116 | −7.549 | 332.5 |
| (CH₃)₂CH-Ph-SO₃H | 3.950 | 13.310 | −7.252 | 333.3 |

*Ph = phenyl

As can be seen from Tables 1 and 2, it is due to the low IP level that PFI itself has (that is, the absolute increases in the direction away from the vacuum level) that the work function of the organic material solution of PEDOT/PSS/PFI increases as the content of PFI increases.

### EXAMPLE 1

Corning 15Ω/cm² (150 nm) ITO glass substrate was cut to a size of 50 mm×50 mm×0.7 mm, and was cleansed in a neutral detergent water solution, pure water, and isopropyl alcohol, each for 15 minutes, and then cleansed with UV ozone for 15 minutes.

1.35 weight % of the organic material solution obtained in Manufacturing Example 1 was spin-coated on the substrate to form a hole injection layer to a thickness of 60 nm.

A red luminescent polymer (LUMATION RP158, available from Sumimoto Corporation) was dissolved with toluene to 1.2 wt % on the hole injection layer to form an emissive layer having a thickness of 80 nm, and then 3.5 nm of Ba and 200 nm of Al was formed as a second electrode on the emissive layer to complete the formation of an organic light emitting device. The organic light emitting device manufactured here is referred to as Sample 1.

### EXAMPLE 2

An organic light emitting device was manufactured in the same manner as in Example 1, except that an organic material solution obtained from Manufacturing Example 2 using the hole injection layer forming material was used. The organic light emitting device manufactured here is referred to as Sample 2.

### EXAMPLE 3

An organic light emitting device was manufactured in the same manner as in Example 1, except that an organic material solution obtained from Manufacturing Example 3 using the hole injection layer forming material was used. The organic light emitting device manufactured here is referred to as Sample 3.

### COMPARATIVE EXAMPLE 1

An organic light emitting device was manufactured in the same manner as in Example 1, except that PEDOT/PSS water solution of Barton P Al 4083 by H. C. Starck was used as the hole injection layer forming material. The organic light emitting device manufactured here is referred to as Comparative Sample A.

### EXAMPLE 4

An organic light emitting device was manufactured in the same manner as in Example 3, except that indium zinc oxide (IZO, work function: 5.1 eV) was used instead of ITO (work function: 4.9 eV), and a green polymer material (LUMATION Green K2, available from Sumitomo) solution was used. The organic light emitting device manufactured here is referred to as Sample 4.

### COMPARATIVE EXAMPLE 2

An organic light emitting device was manufactured in the same manner as in Example 4, except that PEDOT/PSS water solution of Barton P Al 4083 by H. C. Starck was used as the hole injection layer forming material. The organic light emitting device manufactured here is referred to as Comparative Sample B.

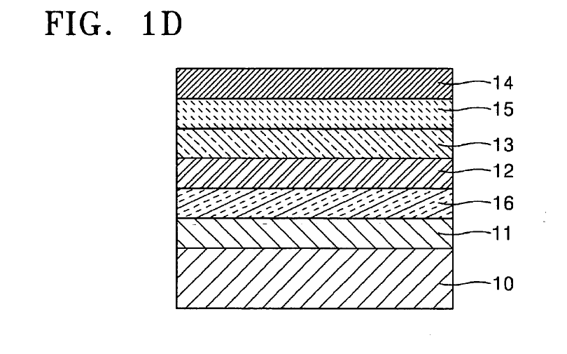

In order to analyze the component of the composition in the depth direction of the thin film, the thin films of Comparative Sample A and Sample 3 were analyzed by measurement of X-ray photoelectron spectroscopy. FIGS. 2A and 2B illustrate the composition of the molecule element in the depth direction, which is obtained by fitting of S2p spectrum. Component analysis was performed by extracting components such as PEDOT, sulfonic acid, sulfone and sulfide, etc. from S2P spectrum, and with respect to Comparative Sample having PFI component, C1s analysis was additionally performed, in order to analyze the component of CF₂. Double peaks at 169 eV in S2p spectrum were allocated as sulfonic acid (—SO₃H), and components at 168.4 and 168.9 eV were allocated as PSS⁻ salt form and PSSH. A very small peak was present at 166.6 eV and this potion was allocated as sulfone (—SO₂—) peak for satisfactory fitting.

Comparative Sample A is formed of only PEDOT and PSS, and PSS remains on a wide range of the surface, but then deceases suddenly and shows a flat distribution until a sputter time of 22 minutes (see FIG. 2A). However, in Sample 3, PFI (—CF₂— peak) is distributed on the surface very much, and as the sputtering time passes, it shows a reducing distribution (see FIG. 2B). Accordingly, it is evident that PFI has a concentration gradient from the surface of the thin film to the bottom of the thin film. Such a concentration gradient causes the gradation of the work function of the thin film (absolute value of ionization energy or HOMO).

As a result, the content of PFI increases gradually toward the surface of the organic layer formed on the first electrode in the organic light emitting device, and the value of the work function increases from the bottom toward the surface.

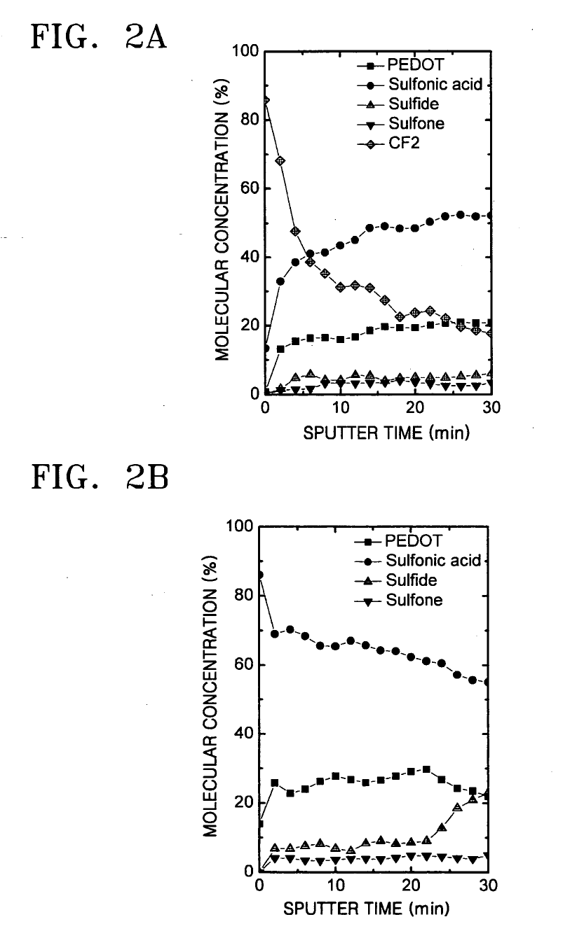

FIG. 3 illustrates energy diagrams of organic light emitting devices, in which a conventional hole injection layer formed of PEDOT/PSS and a hole injection layer formed of PEDOT/PSS/PFI of the present invention, respectively, are compared. As can be seen from the organic light emitting device formed of PEDOT/PSS/PFI, as the work function of the hole injection layer increases gradually, holes can be effectively injected despite the high energy barrier between the ITO electrode and the emissive layer.

Evaluation Example 1—Efficiency Characteristic Evaluation I

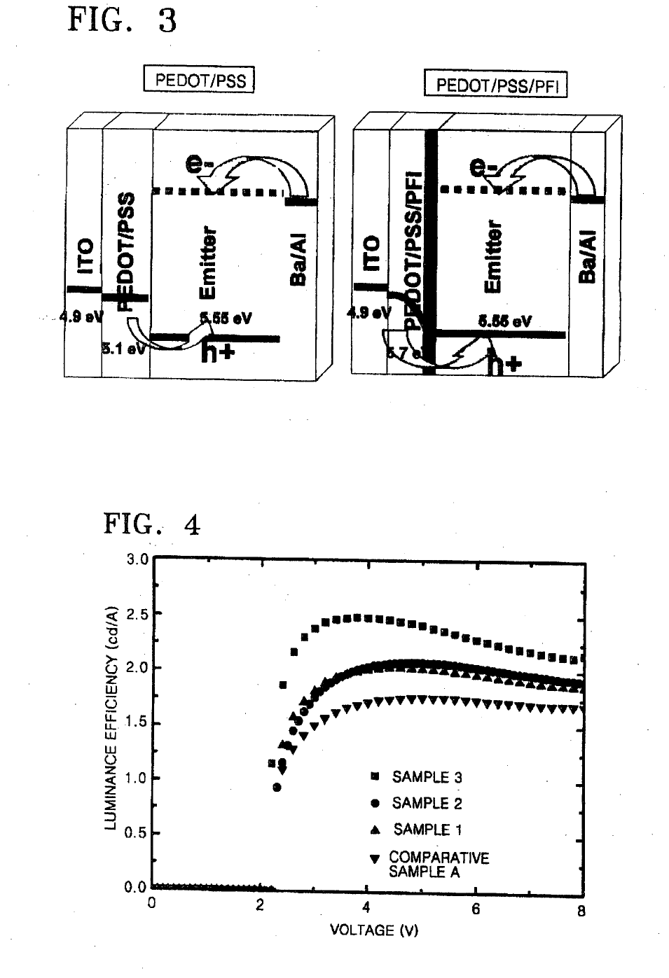

The efficiencies of Samples 1, 2, 3, and Comparative Sample A were measured using a spectroradiometer SpectraScan PR 650. The results are illustrated in FIG. 4. FIG. 4 is a graph illustrating efficiency characteristics of the organic light emitting devices manufactured according to Samples 1, 2, 3, and Comparative Sample A.

Sample 1 showed efficiency of about 2.0 cd/A, Sample 2 showed 2.05 cd/A, and Sample 3 showed 2.5 cd/A, and Comparative Sample A showed about 1.75 cd/A. Accordingly, the efficiency was improved by about 14 to 43%.

Accordingly, it is evident that an organic light emitting device including a hole injection layer formed of the organic material solution of the present invention 11 has excellent luminescent efficiency.

Evaluation Example 2—Efficiency Characteristic Evaluation II

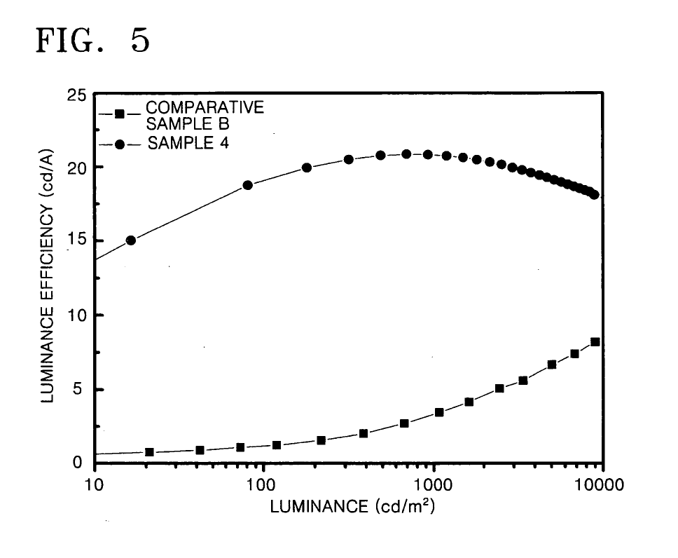

The efficiencies of Sample 4 and Comparative Sample B measured using a spectroradiometer SpectraScan PR 650. The results are illustrated in FIG. 5. FIG. 5 is a graph illustrating efficiency characteristics of the organic light emitting devices manufactured according to Sample 4 and Comparative Sample B.

Sample 4 showed efficiency of 20.8 cd/A, and Comparative Sample B showed efficiency of about 9.8 cd/A. Accordingly, the efficiency was improved by about 210%.

Accordingly, it is evident that an organic light emitting device including a hole injection layer formed of the organic material solution of the present invention has excellent luminescent efficiency.

Evaluation Example 3—Lifetime Evaluation

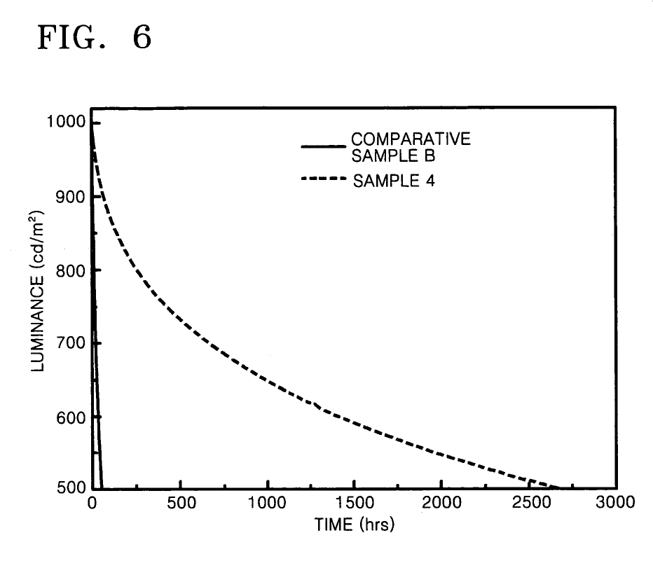

The lifetimes of Sample 4 and Comparative Sample B were measured. Lifetime is measured by measuring brightness according to time using a photodiode, and can be expressed by the time when the initial luminescent brightness is reduced to 50%. The results are illustrated in FIG. 6. FIG. 6 is a graph illustrating the lifetimes of the organic light emitting devices manufactured according to Sample 4 and Comparative Sample B.

Sample 4 has a lifetime of 2680 hours at the initial brightness of 1,000 cd/m², and Comparative Sample B, it has a lifetime of 52 hours. Thus it is evident that the organic light emitting device of the present invention has a lifetime that is 1 increased by about 5,000% or greater compared to a conventional organic light emitting device.

Accordingly, as described above, a conventional PEDOT/PSS conducting polymer composition has a low work function from 5.0 to 5.2 eV, while the PEDOT/PSS/PFI composition has a very high work function (5.55 through 5.95 eV). Thus, when a conductive thin layer is designed such that the concentration-of PFI of the conducting polymer composition PEDOT/PSS/PFI increases selectively from the ITO electrode to the emissive layer, holes can be effectively injected from the electrode into the emissive layer. Accordingly, luminescence efficiency of the organic light emitting device can be greatly increased.

Also, since PFI does not show acidity and is mainly concentrated at the surface, it can effectively block In and Sn from moving from the ITO electrode to the emissive layer due to the presence of PSS, which as a strong acid, erodes the ITO electrode. Time-of-Flight Secondary Ion Mass Spectroscopy (SIMS) showed that the content of In and Sn was reduced to less than 1/10. Accordingly, this can improve the lifetime of the organic light emitting device.

As a result, the lifetime and brightness efficiency of the organic light emitting device can be improved.

The organic light emitting device of the present invention includes an organic layer, the absolute values of the work function, the ionization energy, or the HOMO of which have a gradually increasing gradient, thereby facilitating hole injection from the first electrode to the emissive layer and thus an organic light emitting device having high efficiency and a long lifetime can be obtained.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light emitting device comprising:
a first electrode;
an emissive layer formed on the first electrode;
a second electrode formed on the emissive layer; and
an organic layer interposed between the first electrode and the emissive layer, the organic layer comprising at least two organic materials, at least one of said at least two organic materials having a concentration gradient in the direction from the first electrode to the second electrode.

2. The organic light emitting device of claim 1, further comprising at least one another organic layer comprising at least one organic material between the first electrode and the emissive layer, and at least one organic material of said at least one another organic layer has no concentration gradient in the direction from the first electrode to the second electrode.

3. The organic light emitting device of claim 1, wherein the organic layer is a hole injection layer or a hole transporting layer.

4. The organic light emitting device of claim 1, wherein said at least one of said at least two organic materials has a concentration gradient decreasing in the direction from the first electrode to the second electrode.

5. The organic light emitting device of claim 1, wherein the absolute values of the ionization energy, the work function, and highest occupied molecular orbital (HOMO) in the organic layer increase in the direction from the first electrode to the second electrode.

6. The organic light emitting device of claim 1, wherein the organic layer is formed by self-organization through a single solution process.

7. The organic light emitting device of claim 6, wherein the single solution process comprises dissolving said at least two organic materials in a solvent, coating said at least two organic materials in the solvent on the first electrode, drying the coated organic materials, and heat treating the dried organic materials.

8. The organic light emitting device of claim 1, wherein the organic layer comprises a conjugated compound and a compound represented by Formula 1: 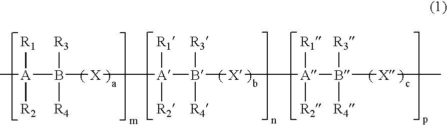
where 0<m<10,000,000, 0≦n<10,000,000, 0≦p<10,000,000, 0≦a≦20, 0≦b≦20, 0≦c≦20;
A, B, A′, B′, A″, and B″ are each independently selected from C, Si, Ge, Sn, and Pb;
R₁, R₂, R₃, R₄, R₁′, R₂′, R₃′, R₄′, R₁″, R₂″, R₃″, and R₄″ are each independently selected from the group consisting of hydrogen, halogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group, and a substituted or unsubstituted C6-C30 heteroarylester group;
when n>0, at least one of R1, R₂, R₃, R₄, R₁′, R₂′, R₃′, and R₄′ is fluorine or a group substituted with fluorine, and at least one of R₁, R₂, R₃, and R₄ is an ionic group or comprises an ionic group;
when n=0, at least one of R₁, R₂, R₃, and R₄ is fluorine or a group substituted with fluorine, and at least one of R₁, R₂, R₃, and R₄ is an ionic group or comprises an ionic group; and
X, X′, and X″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, where X, X′, and X″ may be selectively substituted or unsubstituted with fluorine.

9. The organic light emitting device of claim 8, wherein the conjugated compound is a conductive compound substituted or unsubstituted with an ionic group or a semi-conductive compound that is substituted or unsubstituted with an ionic group.

10. The organic light emitting device of claim 9, wherein the conductive compound is selected from the group of polymers consisting of ethylenedioxythiophene (EDOT), aniline, pyrrole, acetylene, phenylene, phenylenevinylene, thiophene, and oligomer and polymer of derivatives thereof.

11. The organic light emitting device of claim 9, wherein the semi-conductive compound has at least one of the recurring units represented by Formulas 1A through 1AA, and has a polymerization degree of 1 through 10,000,000: 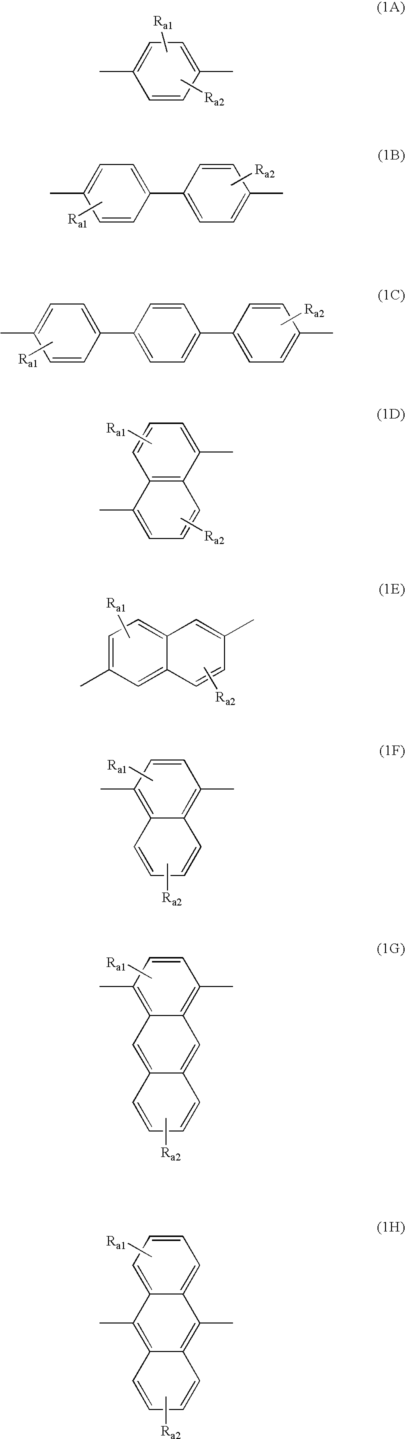 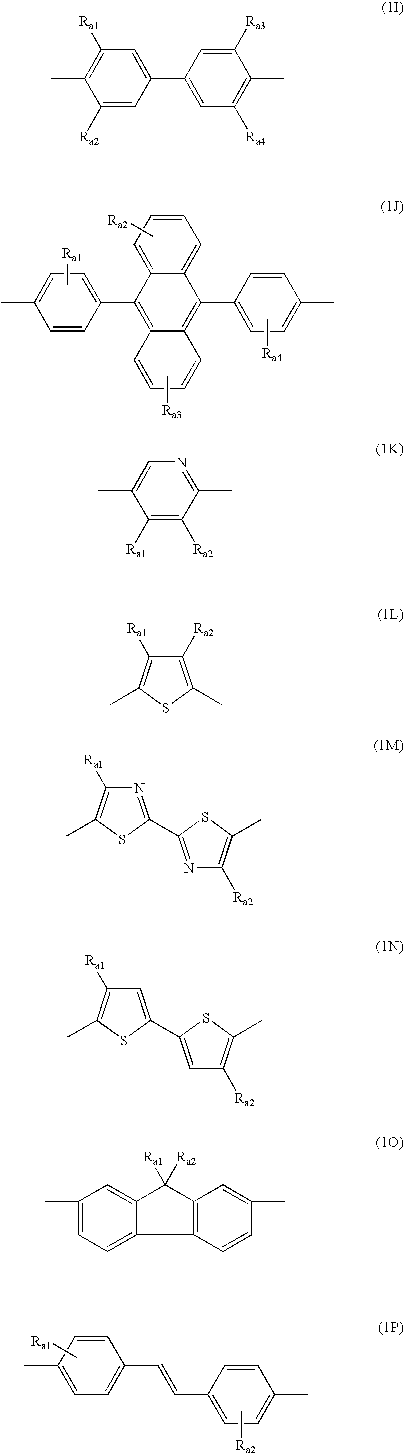 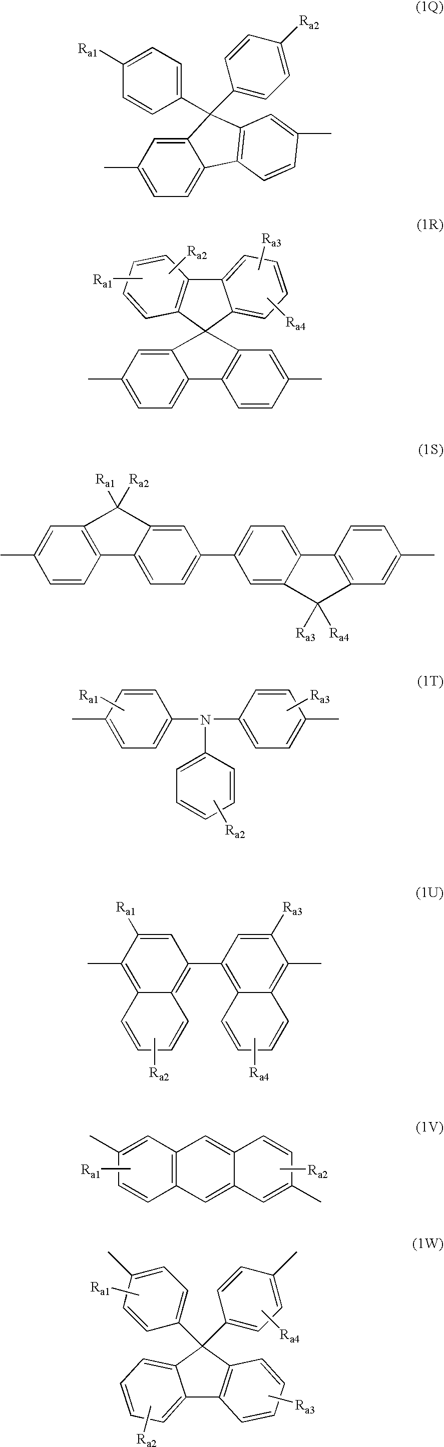 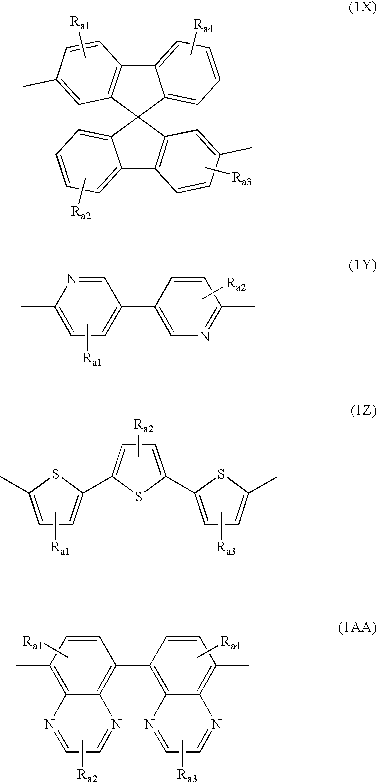
where Rₐ₁, Rₐ₂, Rₐ₃, and Rₐ₄ are each an ionic group, hydrogen, a substituted or unsubstituted C1-C12 alkyl group, a substituted or unsubstituted C1-C12 alkoxy group, a substituted or unsubstituted C6-C20 aryl group, or —N(R′)(R″) where R′ and R″ are each hydrogen, or a substituted or unsubstituted C1-C12 alkyl group.

12. The organic light emitting device of claim 8, wherein at least one of the conjugated compound and the compound represented by Formula 1 has a concentration gradient in the direction from the first electrode to the second electrode.

13. The organic light emitting device of claim 8, wherein the concentration of the compound represented by Formula 1 in the organic layer increases in the direction from the first electrode to the second electrode.

14. The organic light emitting device of claim 8, wherein the compound represented by Formula 1 is 10 to 5,000 parts by weight based on 100 parts by weight of the conjugated compound.

15. The organic light emitting device of claim 8, wherein the ionic group comprises an anionic group and a cationic group paired with the anionic group, the anionic group is PO₃²⁻, SO₃⁻, COO⁻, I⁻, or CH₃COO⁻, and the cationic group is a metal ion selected from the group consisting of Na⁺, K⁺, Li⁺, Mg⁺², Zn⁺², and Al⁺³; or an organic ion selected from the group consisting of H⁺, NH₃⁺, and CH₃(—CH₂—)ₙO⁺ where n is a natural number from 1 to 50.

16. The organic light emitting device of claim 8, wherein, in the compound represented by Formula 1, m=1, n=0, and p=0, and the compound represented by Formula 1 is a fluorocarbon polymer.

17. The organic light emitting device of claim 8, wherein the compound represented by Formula 1 is a perfluorinated compound.

18. The organic light emitting device of claim 8, wherein the compound represented by Formula 1 is represented by Formulas 2 through 12: 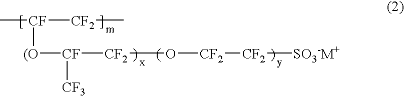
where m is in the range of 1 to 10,000,000, and x and y are each in the range of 0 to 10, M⁺ is Na⁺, K⁺, Li⁺, H⁺, CH₃(CH₂)ₙNH₃⁺ where n is an integer from 0 through 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 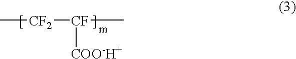
where m is in the range from 1 to 10,000,000; 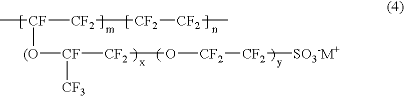
where 0<m≦10,000,000, 0≦n<10,000,000, and x and y are each in the range of 0 to 20, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 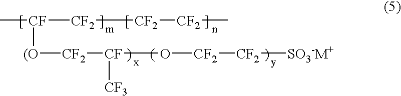
where 0<m≦10,000,000, 0≦n<10,000,000, and x and y are each in the range of 0 to 20, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 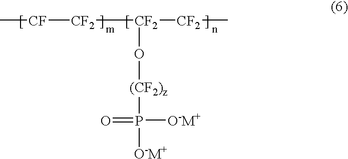
where 0<m≦10,000,000, 0≦n<10,000,000, z is an integer from 0 through 20, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 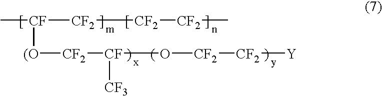
where 0<m≦10,000,000, 0<n<10,000,000, and x and y are each in the range of 0 to 20, Y is one selected from —COO⁻M⁺, —SO₃⁻NHSO₂CF₃⁺, and —PO₃²⁻(M⁺)₂, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 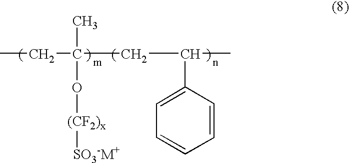
where 0<m≦10,000,000, 0≦n<10,000,000, and x and y are each in the range of 0 to 20, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 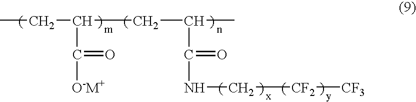
where 0<m≦10,000,000, 0≦n<10,000,000, and x and y are each in the range of 0 to 20, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 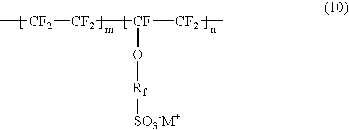
where 0≦m<10,000,000, 0<n≦10,000,000, R_{f}=—(CF₂)ₙ⁻ where z is 1 or an integer from 3 to 50, —(CF₂CF₂O)_{z}CF₂CF₂— where z is an integer from 1 to 50, —(CF₂CF₂CF₂O)_{z}CF₂CF₂— where z is an integer from 1 to 50), M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 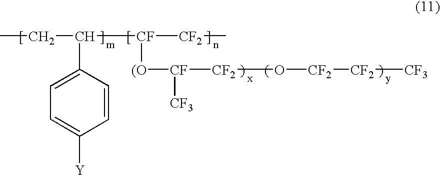
where m and n 0≦m<10,000,000, 0<n≦10,000,000, x and y are each in the range of 0 to 20, Y is one selected from the group consisting of —SO₃⁻M⁺, —COO⁻M⁺, —SO₃⁻NHSO₂CF3⁺, and —PO₃²⁻(M⁺)₂, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; and 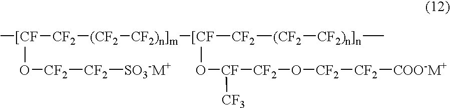
where 0≦m<10,000,000, 0<n≦10,000,000, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50.

19. The organic light emitting device of claim 8, wherein the organic layer further comprises a compound represented by Formula 13: 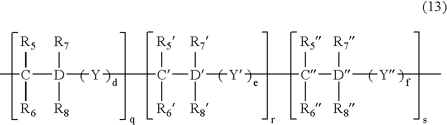
where 0<q<10,000,000, 0≦r<10,000,000, 0≦s<10,000,000, 0≦d≦20, 0≦e≦20, and 0≦f≦20;
C, D, C′, D′, C″, and D″ are each independently selected from the group consisting of C, Si, Ge, Sn, and Pb;
R₅, R_{6,} R₇, R₈, R₅′, R₆′, R₇′, R₈′, R₅″, R₆″, R₇″, and R₈″ are each independently selected from the group consisting of hydrogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group and a substituted or unsubstituted C6-C30 heteroarylester group, and the substituent of the substituted group is not fluorine;
at least one of R₆, R₇, R₈, R₉, R₆′, R₇′, R₈′, and R₉′ is an ionic group or comprises an ionic group; and
Y, Y′, and Y″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, and the substituent of the substituted group is not fluorine.

20. The organic light emitting device of claim 19, wherein at least one of the compound represented by Formula 1 and the compound represented by Formula 13 has a concentration gradient in the direction from the first electrode to the second electrode.

21. The organic light emitting device of claim 19, wherein the concentration of the compound represented by Formula 13 decreases in the direction from the first electrode to the second electrode.

22. The organic light emitting device of claim 19, wherein the compound represented by Formula 13 is 10 to 5,000 parts by weight based on 100 parts by weight of the conjugated compound.

23. The organic light emitting device of claim 19, wherein the ionic group comprises an anionic group and a cationic group paired with the anionic group, the anionic group is selected from the group consisting of PO₃²⁻, SO₃⁻, COO⁻, I⁻, and CH₃COO⁻, and the cationic group is a metal ion selected from the group consisting of Na⁺, K⁺, Li⁺, Mg⁺², Zn⁺², and Al⁺³, or an organic ion selected from the group consisting of H⁺, NH₃⁺, and CH₃(—CH₂—)ₙO⁺ where n is a natural number from 1 to 50.

24. The organic light emitting device of claim 19, wherein the compound represented by Formula 13 is one of Formulas 14 through 16: 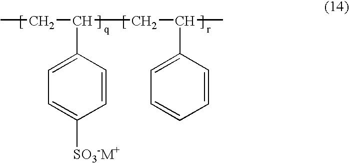
where 0<q≦10,000,000, 0≦r<10,000,000, M⁺ is N^{a+}, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; 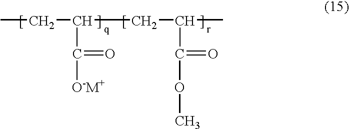
where 0<q≦10,000,000, 0≦r<10,000,000, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, or RCHO⁺ where R is CH₃(CH₂)ₙ⁻ where n is an integer from 0 to 50; and 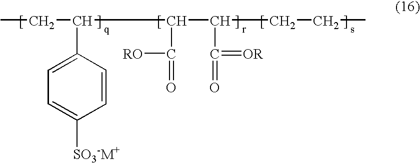
where 0<q≦10,000,000, 0≦r<10,000,000, 0≦s<10,000,000, M⁺ is Na⁺, K⁺, Li⁺, H⁺, CH₃(CH₂)ₙNH₃⁺ where n is an integer from 0 to 50, NH₄⁺, NH₂⁺, NHSO₂CF₃⁺, CHO⁺, C₂H₅OH⁺, CH₃OH⁺, and RCHO⁺ where R is CH₃(CH₂)ₙ⁻ where n is an integer from 0 to 50.

25. The organic light emitting device of claim 8, wherein the organic layer further comprises at least one of a physical cross-linking agent and a chemical cross linking agent.

26. The organic light emitting device of claim 25, wherein the physical cross-linking agent comprises at least one of a small molecule compound selected from the group consisting of glycerol, butanol, polyvinyl alcohol, polyethylene glycol, polyethyleneimine, and polyvinylpyrrolidone and a polymer comprising a hydroxyl group (—OH), and the chemical cross-linking agent is selected from the group consisting of tetraethyloxysilane (TEOS), polyaziridine, melamine material, and epoxy material.

27. The organic light emitting device of claim 8, wherein the organic layer further comprises at least one of metal nanoparticles and inorganic nanoparticles.

28. The organic light emitting device of claim 1, further comprising a hole stopper layer, an electron stopper layer, an electron transporting layer, and an electron injection layer between the first electrode and the second electrode.

29. A compound represented by Formula 1: 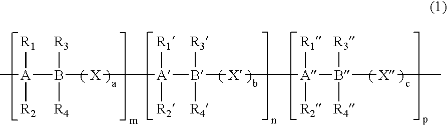
where 0<m<10,000,000, 0≦n<10,000,000, 0≦p<10,000,000, 0≦a≦20, 0≦b≦20, 0≦c≦20;
A, B, A′, B′, A″, and B″ are each independently selected from C, Si, Ge, Sn, and Pb;
R₁, R₂, R₃, R₄, R₁′, R₂′, R₃′, R₄′, R₁″, R₂″, R₃″, and R₄″ are each independently selected from the group consisting of hydrogen, halogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group, and a substituted or unsubstituted C6-C30 heteroarylester group;
when n>0, at least one of R₁, R₂, R₃, R₄, R₁′, R₂′, R₃′, and R₄′ is fluorine or a group substituted with fluorine, and at least one of R₁, R₂, R₃, and R₄ is an ionic group or comprises an ionic group;
when n=0, at least one of R₁, R₂, R₃, and R₄ is fluorine or a group substituted with fluorine, and at least-one of R₁, R₂, R₃, and R₄ is an ionic group or comprises an ionic group; and
X, X′, and X″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, where X, X′, and X″ may be selectively substituted or unsubstituted with fluorine.

30. An organic light emitting device comprising:
a substrate;
a first electrode on the substrate;
an emissive layer formed on the first electrode;
a second electrode formed on the emitting layer; and
an organic layer interposed between the first electrode and the emissive layer, the organic layer comprising a conjugated compound and a compound represented by Formula 1, the organic layer formed by self-organization through a single solution process, at least one of the conjugated compound and the compound represented by Formula 1 having a concentration gradient in the direction from the first electrode to the second electrode: 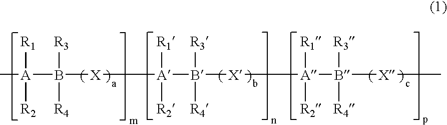
where 0<m<10,000,000, 0≦n<10,000,000, 0≦p<10,000,000, 0≦a≦20, 0≦b≦20, 0≦c≦20;
A, B, A′, B′, A″, and B″ are each independently selected from C, Si, Ge, Sn, and Pb;
R₁, R₂, R₃, R₄, R₁′, R₂′, R₃′, R₄′, R₁″, R₂″, R₃″, and R₄″ are each independently selected from the group consisting of hydrogen, halogen, a nitro group, a substituted or unsubstituted amino group, cyano group, a substituted or unsubstituted C1-C30 alkyl group, a substituted or unsubstituted C1-C30 alkoxy group, a substituted or unsubstituted C6-C30 aryl group, a substituted or unsubstituted C6-C30 arylalkyl group, a substituted or unsubstituted C6-C30 aryloxy group, a substituted or unsubstituted C1-C30 heteroalkyl group, a substituted or unsubstituted C1-C30 heteroalkoxy group, a substituted or unsubstituted C2-C30 heteroaryl group, a substituted or unsubstituted C2-C30 heteroarylalkyl group, a substituted or unsubstituted C2-C30 heteroaryloxy group, a substituted or unsubstituted C5-C20 cycloalkyl group, a substituted or unsubstituted C5-C30 heterocycloalkyl group, a substituted or unsubstituted C1-C30 alkylester group, a substituted or unsubstituted C1-C30 heteroalkylester group, a substituted or unsubstituted C6-C30 arylester group, and a substituted or unsubstituted C6-C30 heteroarylester group;
when n>0, at least one of R₁, R₂, R₃, R₄, R₁′, R₂′, R₃′, and R₄′ is fluorine or a group substituted with fluorine, and at least one of R₁, R₂, R₃, and R₄ is an ionic group or comprises an ionic group;
when n=0, at least one of R₁, R₂, R₃, and R₄ is fluorine or a group substituted with fluorine, and at least one of R₁, R₂, R₃, and R₄ is an ionic group or comprises an ionic group; and
X, X′, and X″ are each independently selected from the group consisting of a bond, O, S, a substituted or unsubstituted C1-C30 alkylene group, a substituted or unsubstituted C1-C30 heteroalkylene group, a substituted or unsubstituted C6-C30 arylene group, a substituted or unsubstituted C6-C30 arylalkylene group, a substituted or unsubstituted C2-C30 heteroarylene group, a substituted or unsubstituted C2-C30 heteroarylalkylene group, a substituted or unsubstituted C5-C20 cycloalkylene group, a substituted or unsubstituted C2-C30 heterocycloalkylene group, a substituted or unsubstituted C6-C30 arylester group, and a substituted or unsubstituted C6-C30 heteroarylester group, where X, X′, and X″ may be selectively substituted or unsubstituted with fluorine.
